(19) United States
(12) Patent Application Publication
(10) Pub. No.: US 2025/0112183 A1
(43) Pub. Date: Apr. 3, 2025

(54) SEMICONDUCTOR DIE AND METHODS OF FORMATION

(71) Applicant: Taiwan Semiconductor Manufacturing Company, Ltd., Hsinchu (TW)

(72) Inventor: Chern-Yow HSU, Hsin-Chu county (TW)

(21) Appl. No.: 18/479,269

(22) Filed: Oct. 2, 2023

(51) Int. Cl. H01L 23/00; H01L 21/66

(52) U.S. Cl. CPC H01L 24/05; H01L 22/32; H01L 24/03; H01L 24/06; H01L 2224/0219; H01L 2224/02331; H01L 2224/03015; H01L 2224/0345; H01L 2224/03452; H01L 2224/03614; H01L 2224/05166; H01L 2224/05557; H01L 2224/05562; H01L 2224/05573; H01L 2224/05666; H01L 2224/05681; H01L 2224/05686; H01L 2224/06051; H01L 2924/10161

(57) ABSTRACT

A highly selective wet etch technique is used to etch a barrier layer under a metal layer from which the test pads of a semiconductor die are formed in a periphery region of the semiconductor die. The wet etch technique involves the use of a wet etchant that has a high etch rate for the barrier layer and a very low etch rate for a top dielectric layer on which the barrier layer is formed. Sidewall spacers may be formed on the sidewalls of the test pads to protect the test pads from being etched by the wet etchant. The low etch rate of the top dielectric layer reduces and/or minimizes over etching into the top dielectric layer, which reduces and/or minimizes the step height between the top dielectric layer and the test pads.

### BACKGROUND

A semiconductor die may be subjected to circuit probe (CP) testing and/or a wafer acceptance testing (WAT) to verify one or more performance parameters of the semiconductor die, to verify one or more design parameters of the semiconductor die, and/or to determine one or more other parameters associated with the semiconductor die.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a diagram of an example environment in which systems and/or methods described herein may be implemented.

FIGS. 2A-2D are diagrams of an example semiconductor die described herein.

FIG. 3 is a diagram of an example implementation of picking up a semiconductor die using a wafer/die transport tool (e.g., a pick and place tool) described herein.

FIGS. 4A-4M are diagrams of an example implementation of forming a semiconductor die described herein.

FIG. 5 is a diagram of example components of a device described herein.

FIG. 6 is a flowchart of an example process associated with forming a semiconductor die described herein.

FIG. 7 is a flowchart of an example process associated with forming a semiconductor die described herein.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Test pads may be formed on a semiconductor die to enable circuit probe (CP) testing and/or a wafer acceptance testing (WAT) to be performed on the semiconductor die prior to a semiconductor wafer, on which the semiconductor die is formed, being diced into individual semiconductor dies. The test pads are formed in the periphery region of the semiconductor die surrounding the active device region of the semiconductor die. The test pads are temporary structures that are subsequently removed and replaced with redistribution pads that are used for routing electrical signals and/or power in the semiconductor die. Redistribution pads are also formed in the active device region.

The test pads may be formed by depositing a metal layer over a top dielectric layer and performing an etch operation to remove portions of the metal layer, where remaining portions of the metal layer correspond to the test pads. In some cases, over etching occurs when etching through a barrier layer between the metal layer and the top dielectric layer. “Over etching” refers to removal of the top dielectric layer adjacent to and/or surrounding the test pads, and results in a relatively large step height between the top dielectric layer and the test pads.

During formation of the redistribution pads, another metal layer is deposited on the top dielectric layer, and the redistribution pads are formed by removing portions of the metal layer. The large step height that resulted from the over etching into the top dielectric layer results in a relatively large difference in height between top surfaces of the redistribution pads in the active device region and top surfaces of the redistribution pads that replace the test pads. The redistribution pads are also used as attachment points by a pick and place tool for moving the semiconductor die to different locations (e.g., to a semiconductor device package, to a storage container), and the large difference in height results in reduced capability of the pick and place tool to obtain a secure hold of the semiconductor die because of the low contact surface between the pick and place tool and the redistribution pads. This can result in an inability of the pick and place tool to pick up the semiconductor die and/or can result in the pick and place tool dropping the semiconductor die, which can damage the semiconductor die and cause the semiconductor die to be nonoperational.

In some implementations described herein, a highly selective wet etch technique is used to etch a barrier layer under a metal layer from which the test pads of a semiconductor die are formed in a periphery region of the semiconductor die. The wet etch technique involves the use of a wet etchant that has a high etch rate for the barrier layer and a very low etch rate (effectively a zero etch rate, in some cases) for a top dielectric layer on which the barrier layer is formed. Sidewall spacers may be formed on the sidewalls of the test pads to protect the test pads from being etched by the wet etchant.

In this way, the low etch rate of the top dielectric layer reduces and/or minimizes over etching into the top dielectric layer, which reduces and/or minimizes the step height between the top dielectric layer and the test pads. Thus, when the test pads are replaced with redistribution pads after testing of the semiconductor die, the difference in height between the redistribution pads in the periphery region and redistribution pads in an active device region of the semiconductor die is reduced and/or minimized. This enables a pick and place tool to utilize more of the surface area of the redistribution pads of the semiconductor die to securely pick up and move the semiconductor die. This increases the productivity of the pick and place tool (the pick and place tool can spend less time attempting to securely pick up and move the semiconductor die, thereby processing a greater quantity of semiconductor dies) and/or reduces the likelihood of damage to the semiconductor die, among other examples.

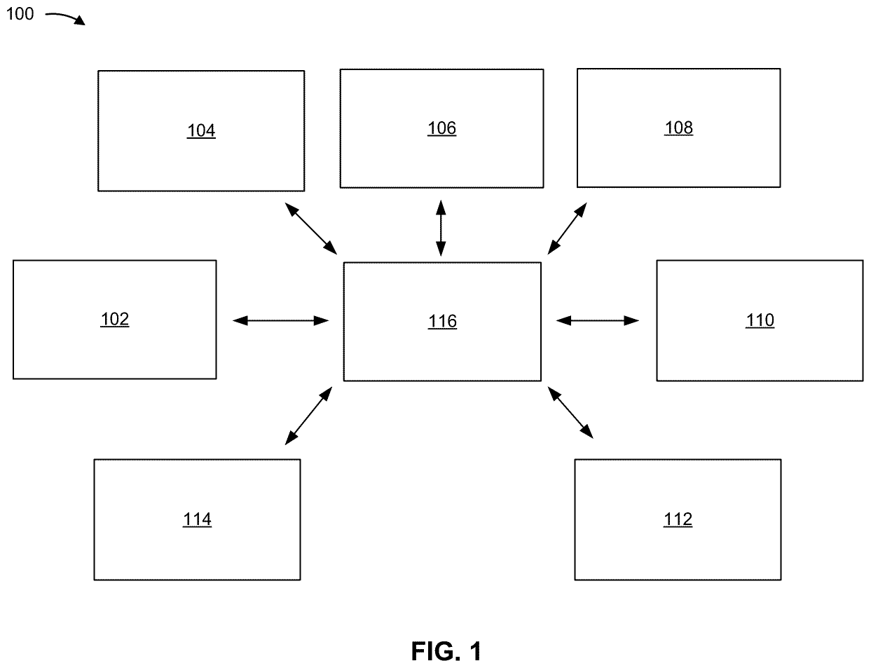

FIG. 1 is a diagram of an example environment 100 in which systems and/or methods described herein may be implemented. As shown in FIG. 1, the example environment 100 may include a plurality of semiconductor processing tools 102-114 and a wafer/die transport tool 116. The plurality of semiconductor processing tools 102-114 may include a deposition tool 102, an exposure tool 104, a developer tool 106, an etch tool 108, a planarization tool 110, a plating tool 112, a wafer testing tool 114, and/or another type of semiconductor processing tool. The tools included in example environment 100 may be included in a semiconductor clean room, a semiconductor foundry, a semiconductor processing facility, and/or manufacturing facility, among other examples.

The deposition tool 102 is a semiconductor processing tool that includes a semiconductor processing chamber and one or more devices capable of depositing various types of materials onto a substrate. In some implementations, the deposition tool 102 includes a spin coating tool that is capable of depositing a photoresist layer on a substrate such as a wafer. In some implementations, the deposition tool 102 includes a chemical vapor deposition (CVD) tool such as a plasma enhanced CVD (PECVD) tool, a low-pressure CVD (LPCVD) tool, a high-density plasma CVD (HDP-CVD) tool, a sub-atmospheric CVD (SACVD) tool, an atomic layer deposition (ALD) tool, a plasma-enhanced atomic layer deposition (PEALD) tool, or another type of CVD tool. In some implementations, the deposition tool 102 includes a physical vapor deposition (PVD) tool, such as a sputtering tool or another type of PVD tool. In some implementations, the example environment 100 includes a plurality of different types of deposition tools 102. “Deposition tool 102,” as used herein, may refer to one or more deposition tools 102, one or more of the same type of deposition tools 102, and/or one or more different types of deposition tools 102, among other examples.

The exposure tool 104 is a semiconductor processing tool that is capable of exposing a photoresist layer to a radiation source, such as an ultraviolet light (UV) source (e.g., a deep UV light source, an extreme UV light (EUV) source, and/or the like), an x-ray source, an electron beam (e-beam) source, and/or the like. The exposure tool 104 may expose a photoresist layer to the radiation source to transfer a pattern from a photomask to the photoresist layer. The pattern may include one or more semiconductor device layer patterns for forming one or more semiconductor devices, may include a pattern for forming one or more structures of a semiconductor device, may include a pattern for etching various portions of a semiconductor device, and/or the like. In some implementations, the exposure tool 104 includes a scanner, a stepper, or a similar type of exposure tool.

The developer tool 106 is a semiconductor processing tool that is capable of developing a photoresist layer that has been exposed to a radiation source to develop a pattern transferred to the photoresist layer from the exposure tool 104. In some implementations, the developer tool 106 develops a pattern by removing unexposed portions of a photoresist layer. In some implementations, the developer tool 106 develops a pattern by removing exposed portions of a photoresist layer. In some implementations, the developer tool 106 develops a pattern by dissolving exposed or unexposed portions of a photoresist layer through the use of a chemical developer.

The etch tool 108 is a semiconductor processing tool that is capable of etching various types of materials of a substrate, wafer, or semiconductor device. For example, the etch tool 108 may include a wet etch tool, a dry etch tool, and/or the like. In some implementations, the etch tool 108 includes a chamber that is filled with an etchant, and the substrate is placed in the chamber for a particular time period to remove particular amounts of one or more portions of the substrate. In some implementations, the etch tool 108 may etch one or more portions of the substrate using a plasma etch or a plasma-assisted etch, which may involve using an ionized gas to isotropically or directionally etch the one or more portions.

The planarization tool 110 is a semiconductor processing tool that is capable of polishing or planarizing various layers of a wafer or semiconductor device. For example, a planarization tool 110 may include a chemical mechanical planarization (CMP) tool and/or another type of planarization tool that polishes or planarizes a layer or surface of deposited or plated material. The planarization tool 110 may polish or planarize a surface of a semiconductor device with a combination of chemical and mechanical forces (e.g., chemical etching and free abrasive polishing). The planarization tool 110 may utilize an abrasive and corrosive chemical slurry in conjunction with a polishing pad and retaining ring (e.g., typically of a greater diameter than the semiconductor device). The polishing pad and the semiconductor device may be pressed together by a dynamic polishing head and held in place by the retaining ring. The dynamic polishing head may rotate with different axes of rotation to remove material and even out any irregular topography of the semiconductor device, making the semiconductor device flat or planar.

The plating tool 112 is a semiconductor processing tool that is capable of plating a substrate (e.g., a wafer, a semiconductor device, and/or the like) or a portion thereof with one or more metals. For example, the plating tool 112 may include a copper electroplating device, an aluminum electroplating device, a nickel electroplating device, a tin electroplating device, a compound material or alloy (e.g., tin-silver, tin-lead, and/or the like) electroplating device, and/or an electroplating device for one or more other types of conductive materials, metals, and/or similar types of materials.

The wafer testing tool 114 includes one or more tools that are capable of performing wafer-level testing of semiconductor dies formed on a semiconductor wafer. The wafer-level testing may include wafer acceptance tests (WATs), circuit probe (CP) tests, and/or other types of electrical tests that are performed prior to dicing the semiconductor wafer into individual semiconductor dies. Examples of wafer-level tests include a bonding test, a continuity test, a resistance test, a current test, and/or a voltage test, among other examples.

Wafer/die transport tool 116 includes a mobile robot, a robot arm, a tram or rail car, an overhead hoist transport (OHT) system, an automated materially handling system (AMHS), a pick and place tool, and/or another type of device that is configured to transport substrates and/or semiconductor devices between semiconductor processing tools 102-112, that is configured to transport substrates and/or semiconductor devices between processing chambers of the same semiconductor processing tool, and/or that is configured to transport substrates and/or semiconductor devices to and from other locations such as a wafer rack, a storage room, and/or the like. In some implementations, a wafer/die transport tool 116 (e.g., a pick and place tool) is configured to place semiconductor dies on a semiconductor device package substrate. The semiconductor dies may be electrically coupled through redistribution layers in the semiconductor device package substrate. In some implementations, wafer/die transport tool 116 may be a programmed device that is configured to travel a particular path and/or may operate semi-autonomously or autonomously. In some implementations, the example environment 100 includes a plurality of wafer/die transport tools 116.

For example, the wafer/die transport tool 116 may be included in a cluster tool or another type of tool that includes a plurality of processing chambers, and may be configured to transport substrates and/or semiconductor devices between the plurality of processing chambers, to transport substrates and/or semiconductor devices between a processing chamber and a buffer area, to transport substrates and/or semiconductor devices between a processing chamber and an interface tool such as an equipment front end module (EFEM), and/or to transport substrates and/or semiconductor devices between a processing chamber and a transport carrier (e.g., a front opening unified pod (FOUP)), among other examples. In some implementations, a wafer/die transport tool 116 may be included in a multi-chamber (or cluster) deposition tool 102, which may include a pre-clean processing chamber (e.g., for cleaning or removing oxides, oxidation, and/or other types of contamination or byproducts from a substrate and/or semiconductor device) and a plurality of types of deposition processing chambers (e.g., processing chambers for depositing different types of materials, processing chambers for performing different types of deposition operations). In these implementations, the wafer/die transport tool 116 is configured to transport substrates and/or semiconductor devices between the processing chambers of the deposition tool 102 without breaking or removing a vacuum (or an at least partial vacuum) between the processing chambers and/or between processing operations in the deposition tool 102, as described herein.

In some implementations, one or more of the semiconductor processing tools 102-114 may perform one or more semiconductor processing operations described herein. For example, one or more of the semiconductor processing tools 102-114 may form one or more semiconductor devices in an active device region of a semiconductor die; may form one or more first metallization layers in a backend region above the one or more semiconductor devices; may form one or more second metallization layers in the backend region in a periphery region of the semiconductor die, where the periphery region surrounds the active device region in a top view of the semiconductor die; may form a top dielectric layer above the backend region after forming the one or more first metallization layers and the one or more second metallization layers; may form a barrier layer on the top dielectric layer; may form a metal layer on the barrier layer; may form a capping layer on the metal layer; may perform a first etch operation to etch the capping layer and the metal layer to form a test pad on the top dielectric layer in the periphery region; and/or may perform, after the first etch operation, a second etch operation to etch the barrier layer such that the barrier layer remains only under the test pad, among other examples.

As another example, one or more of the semiconductor processing tools 102-114 may form one or more semiconductor devices in an active device region of a semiconductor die; may form one or more first metallization layers in a backend region above the one or more semiconductor devices; may form one or more second metallization layers in the backend region in a periphery region of the semiconductor die, where the periphery region surrounds the active device region in a top view of the semiconductor die; may form a top dielectric layer above the backend region after forming the one or more first metallization layers and the one or more second metallization layers; may form a barrier layer on the top dielectric layer; may form a metal layer on the barrier layer; may form a capping layer on the metal layer; may perform a first etch operation to etch the capping layer and the metal layer to form a test pad on the top dielectric layer in the periphery region; may form, after the first etch operation, sidewall spacers on sidewalls of the test pad; and/or may perform, after forming the sidewall spacers, a second etch operation to etch the barrier layer such that the barrier layer remains only under the test pad, among other examples.

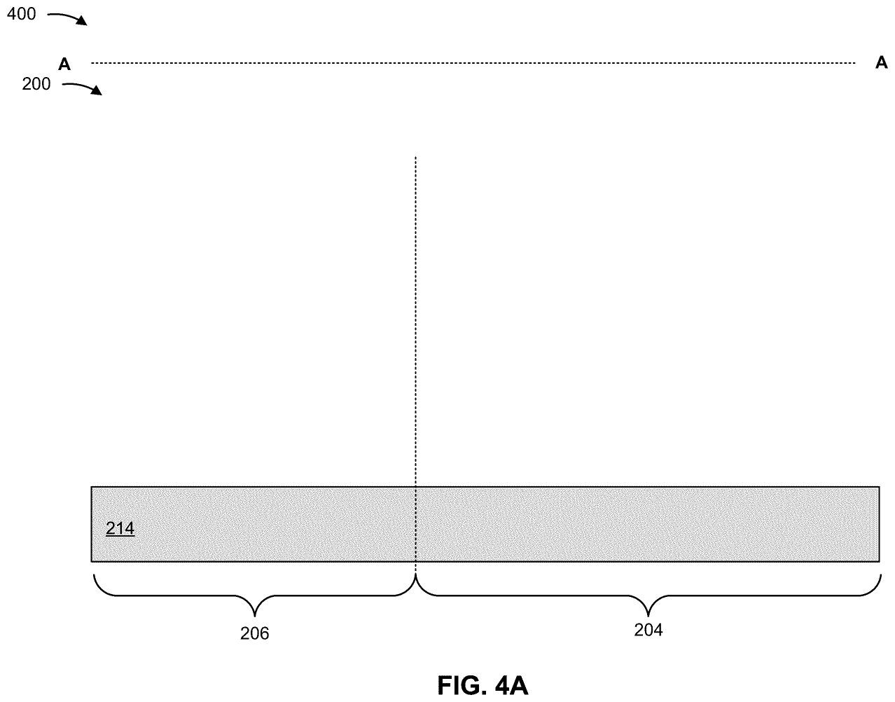

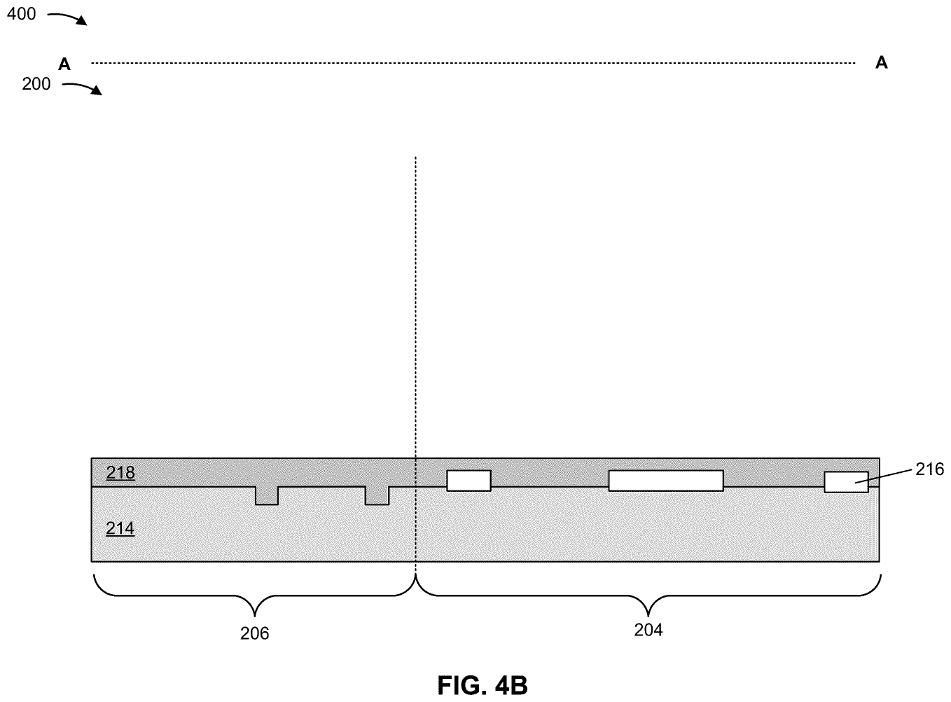

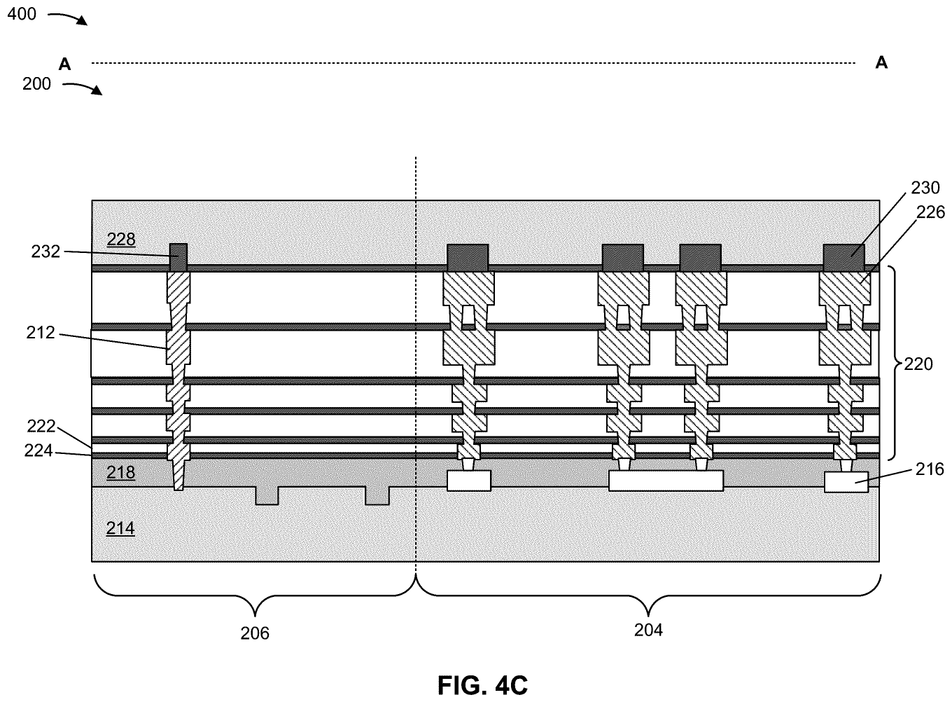

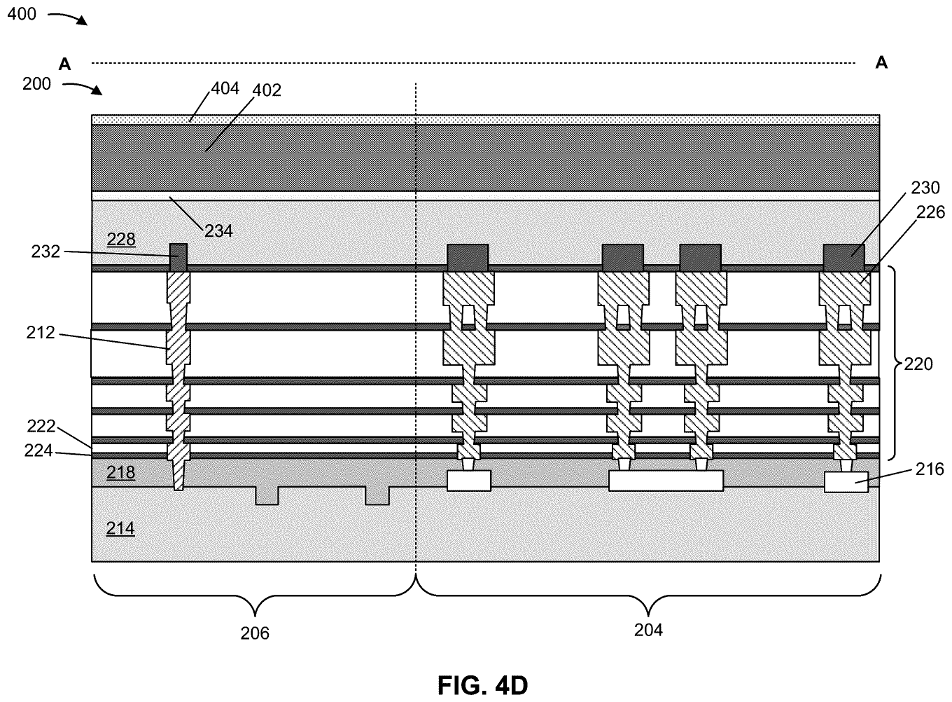

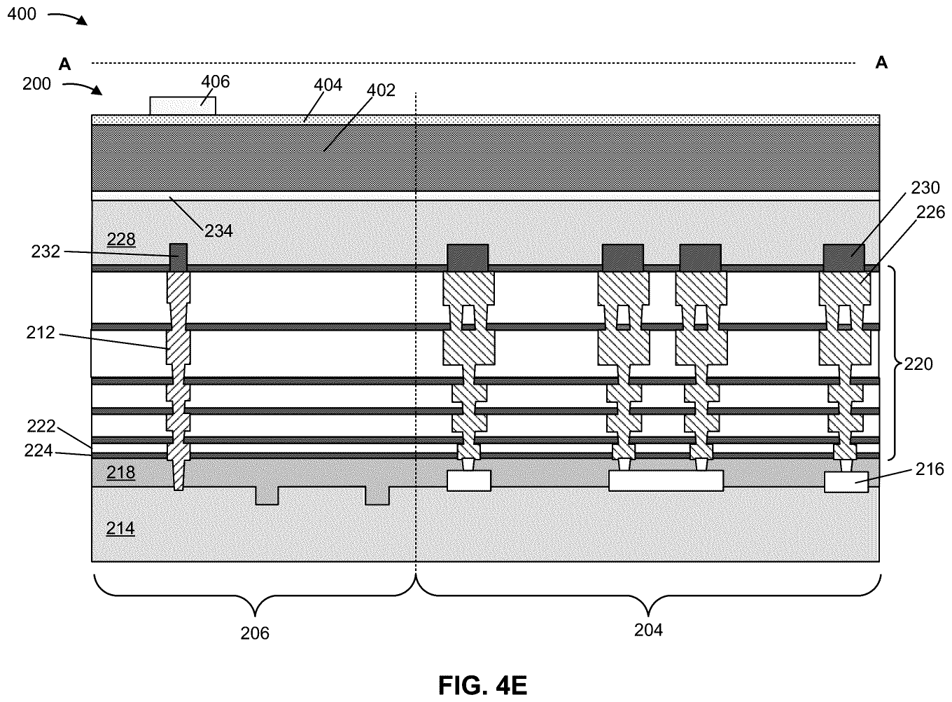

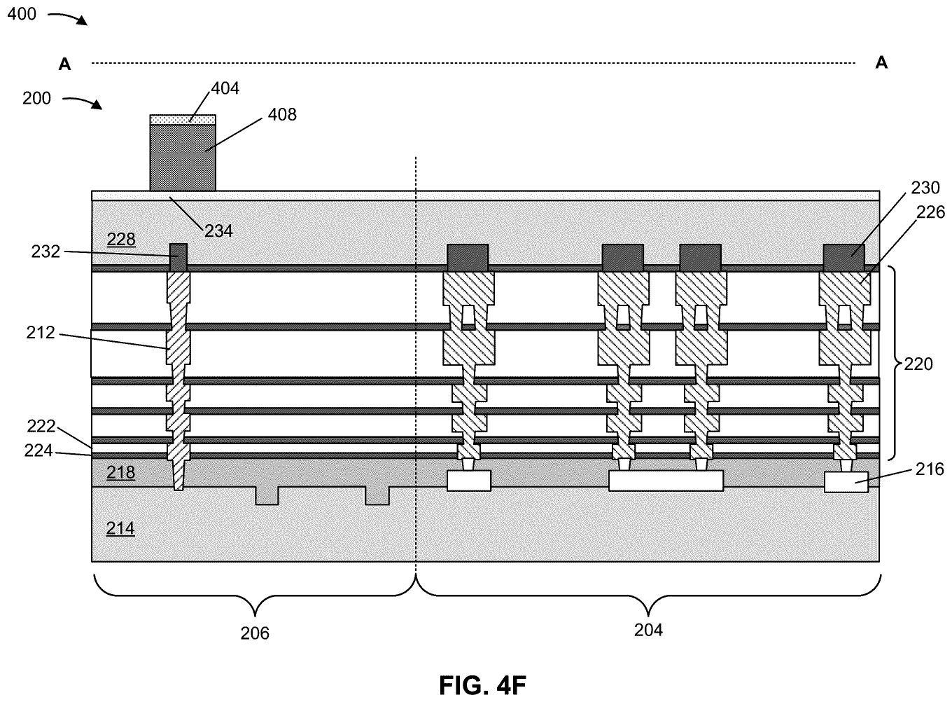

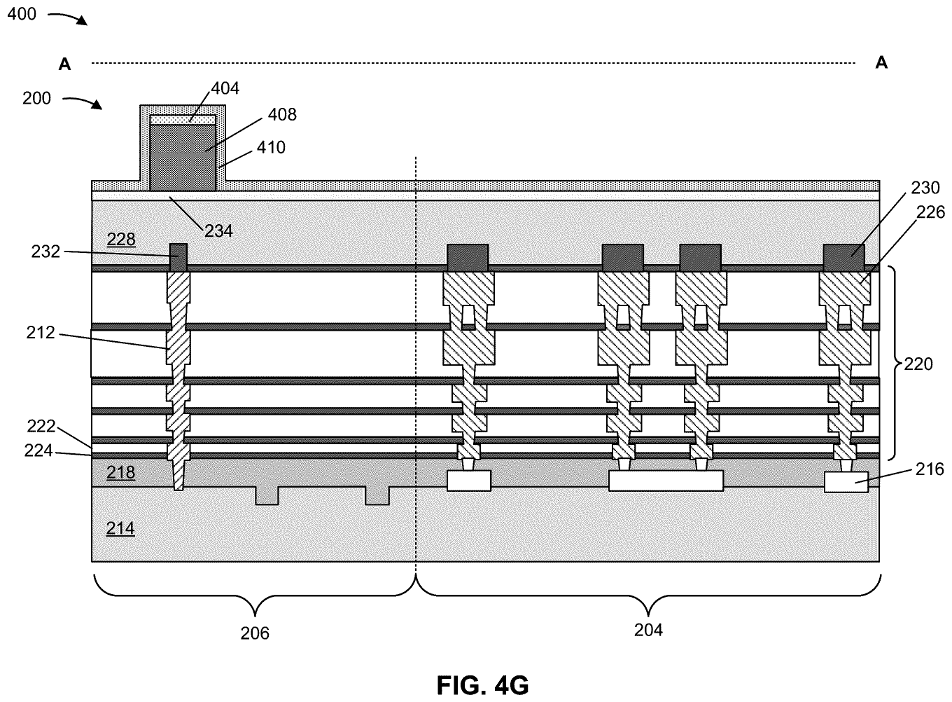

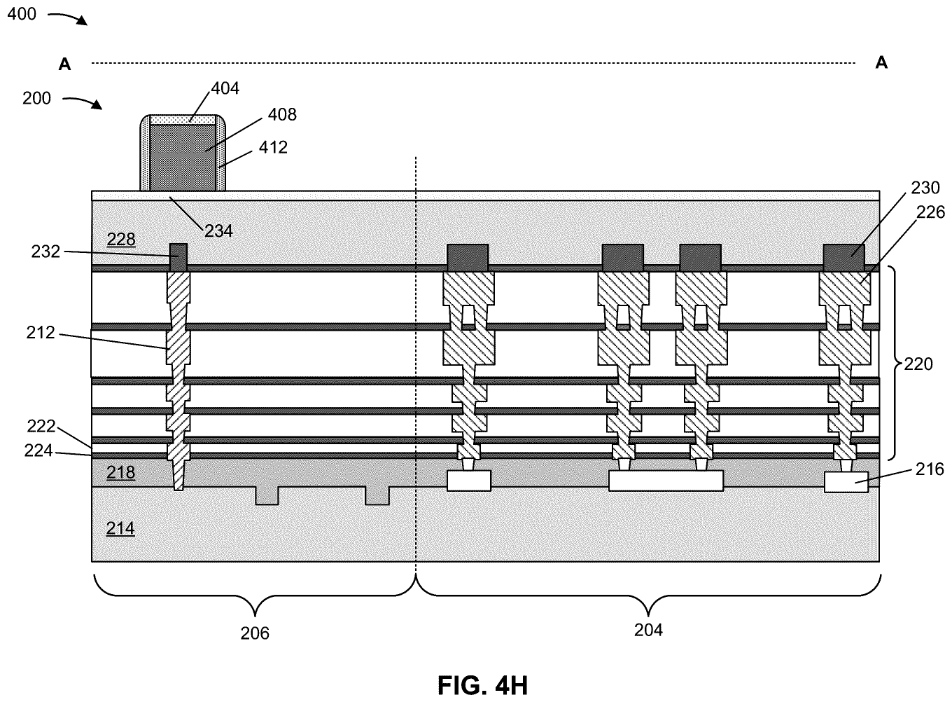

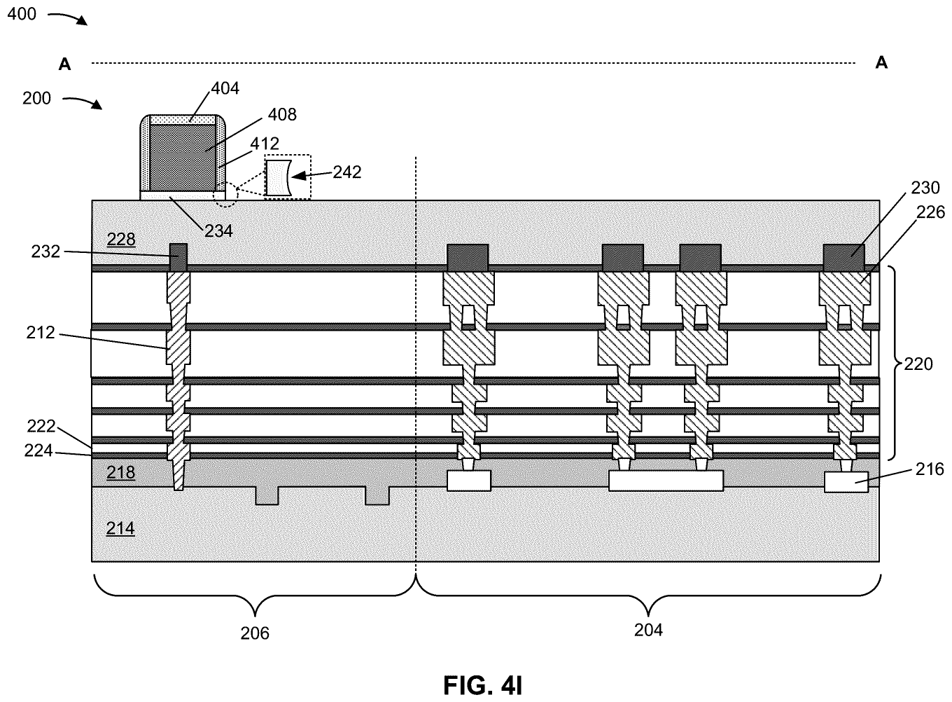

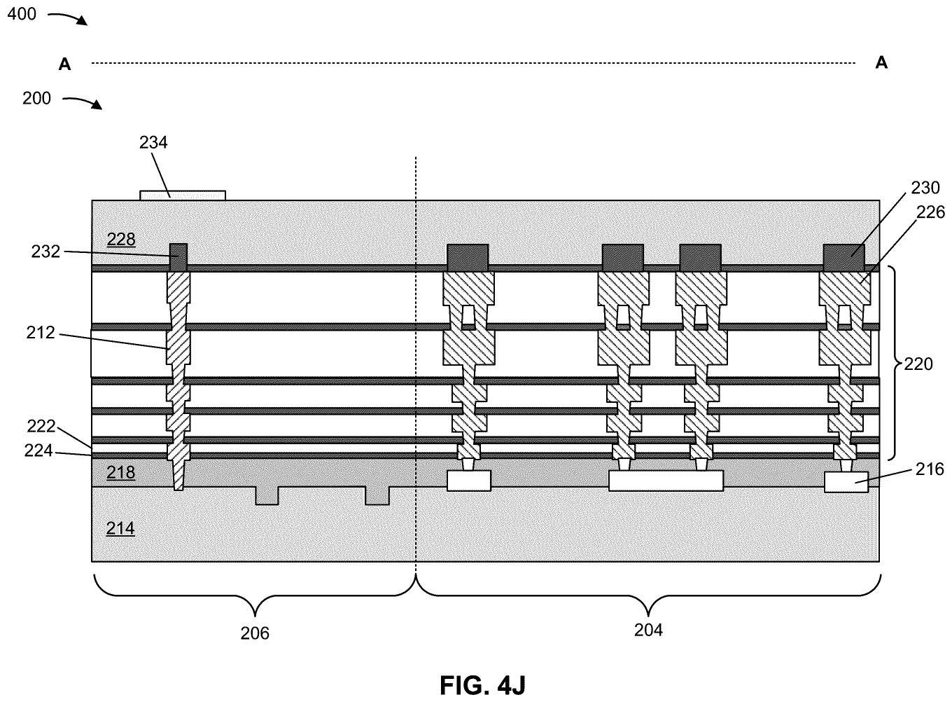

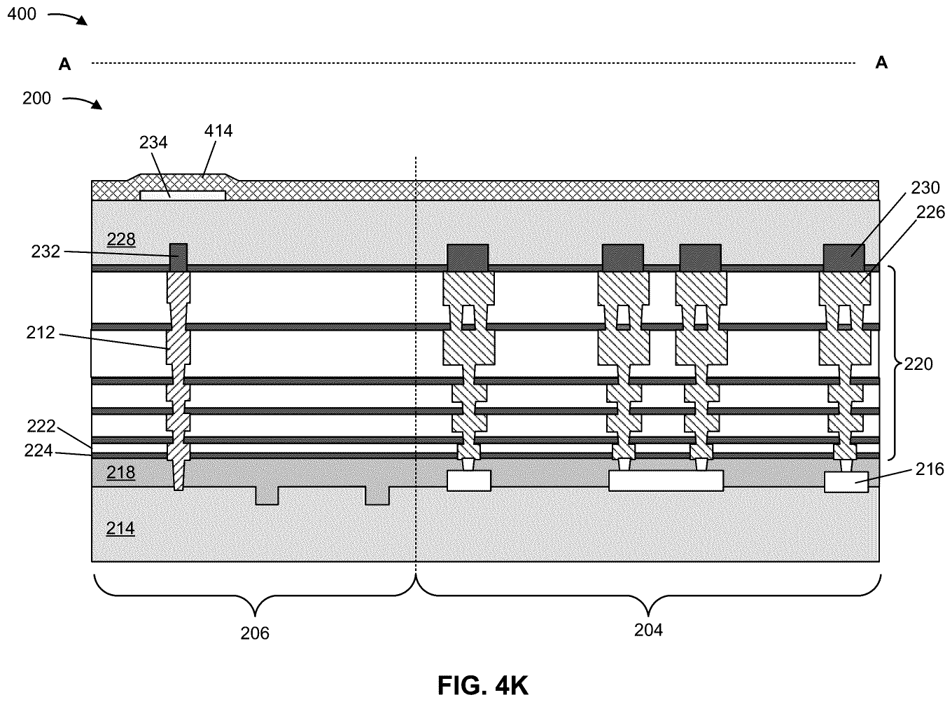

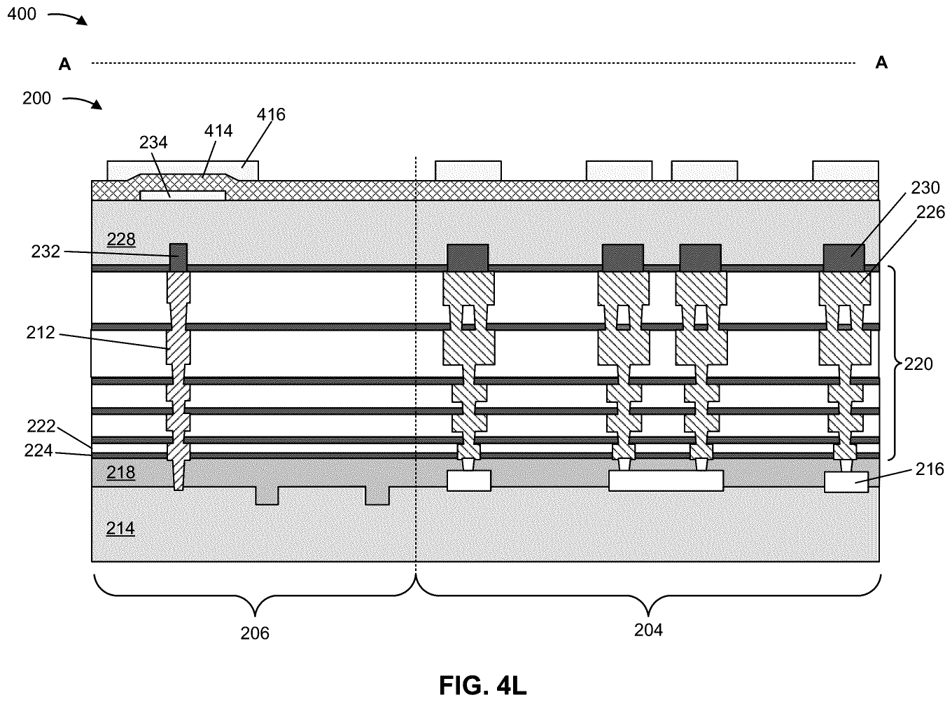

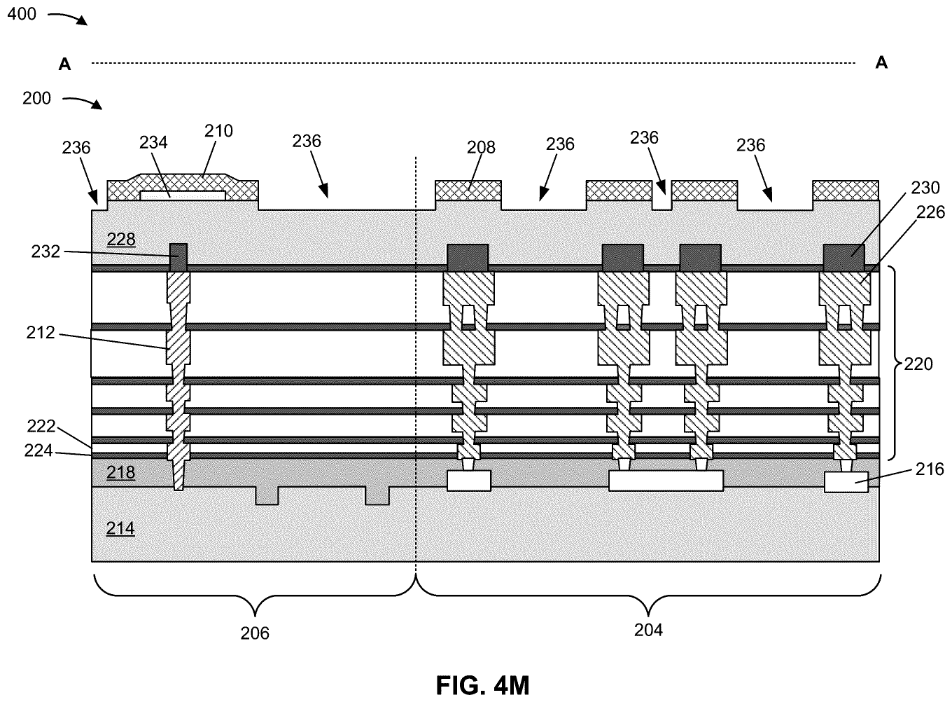

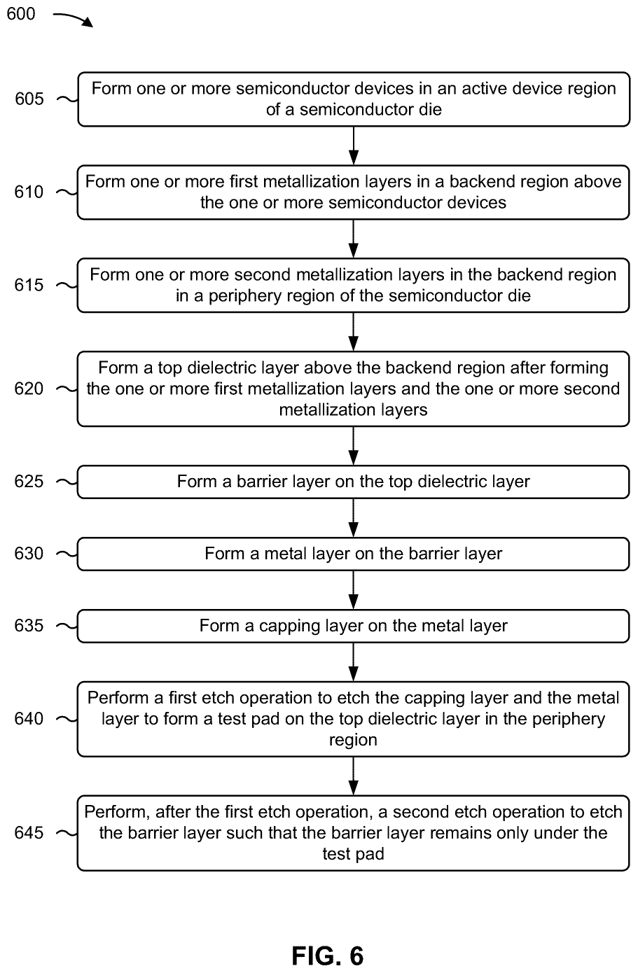

One or more of the semiconductor processing tools 102-114 may perform other semiconductor processing operations described herein, such as in connection with FIGS. 4A-4M, 6, and/or 7, among other examples.

The number and arrangement of devices shown in FIG. 1 are provided as one or more examples. In practice, there may be additional devices, fewer devices, different devices, or differently arranged devices than those shown in FIG. 1. Furthermore, two or more devices shown in FIG. 1 may be implemented within a single device, or a single device shown in FIG. 1 may be implemented as multiple, distributed devices. Additionally, or alternatively, a set of devices (e.g., one or more devices) of the example environment 100 may perform one or more functions described as being performed by another set of devices of the example environment 100.

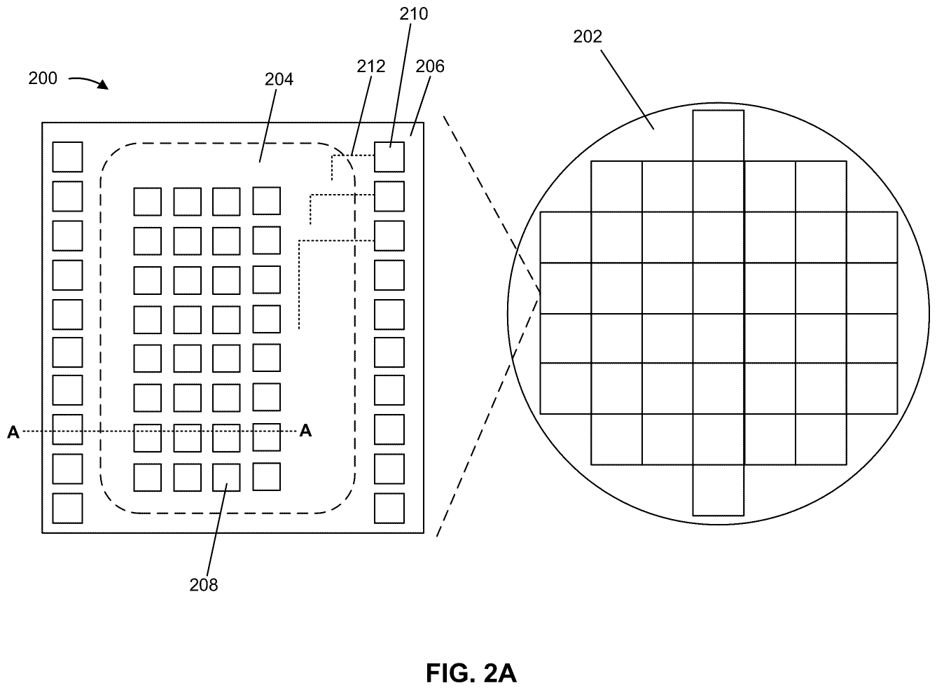

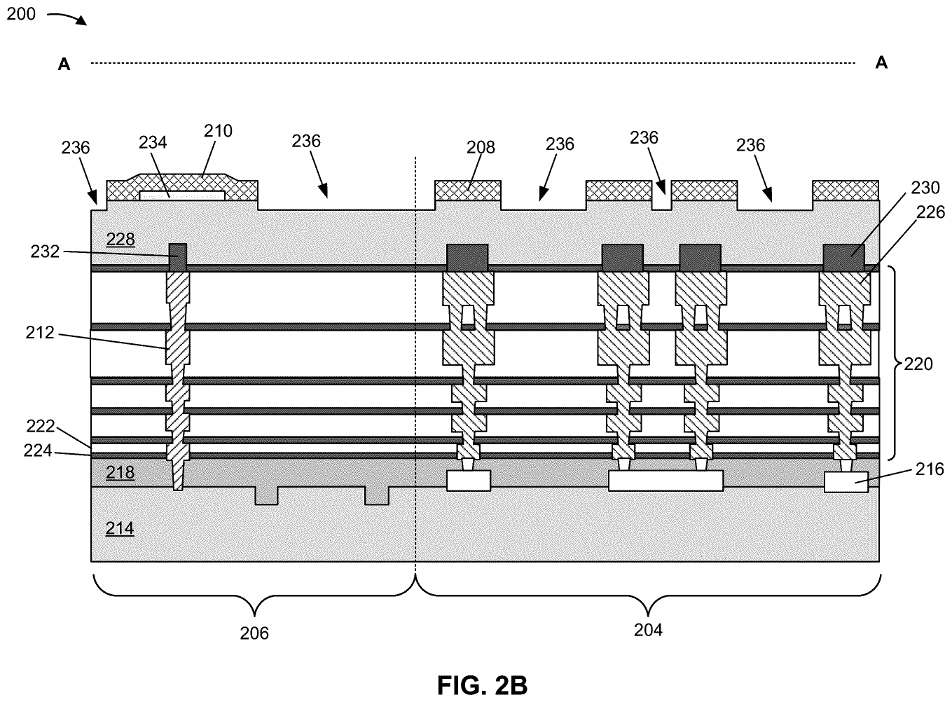

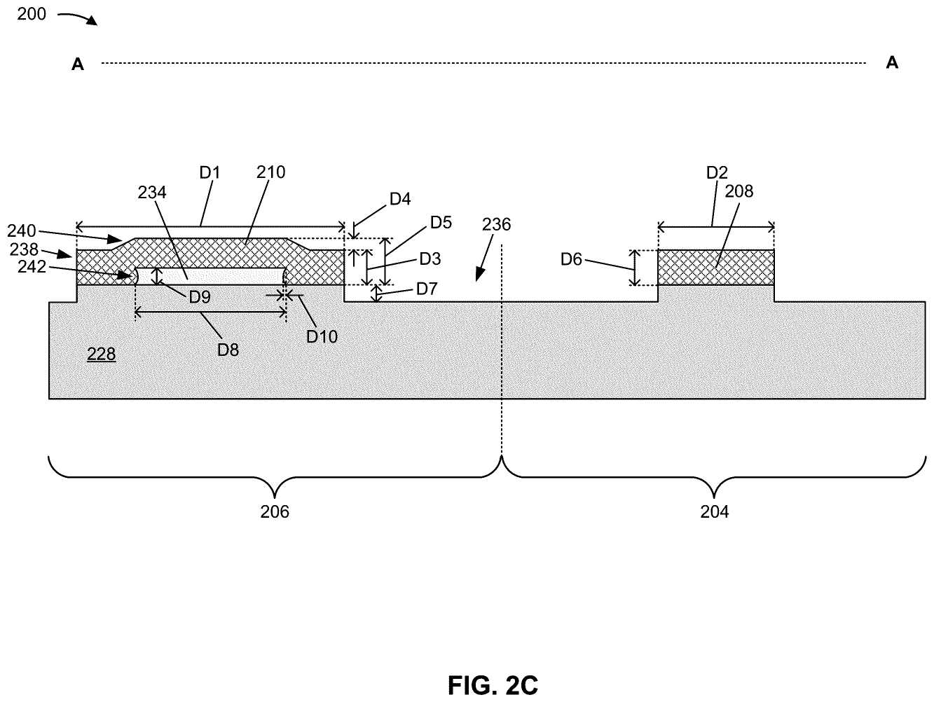

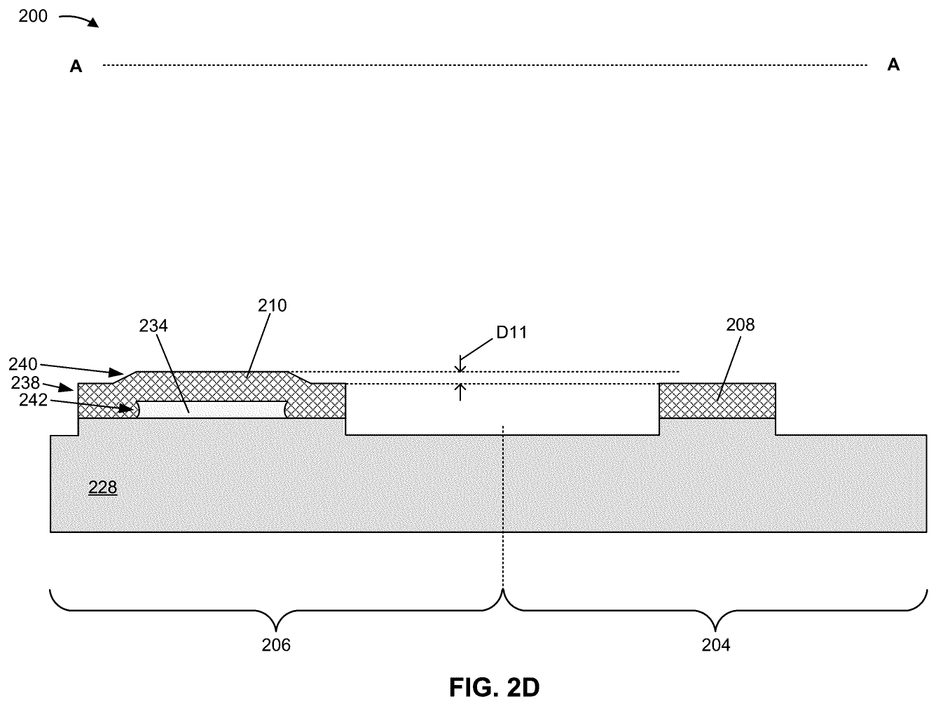

FIGS. 2A-2D are diagrams of an example semiconductor die 200 described herein. In some implementations, the semiconductor die 200 includes a monolithic system on chip (SoC) die that includes a plurality of different functionalities, such as a central processing unit (CPU) die, a graphics processing unit (GPU) die, a digital signal processing (DSP) die, an application specific integrated circuit (ASIC) die, and/or another type of SoC die. In some implementations, the semiconductor die 200 includes a chiplet, which is a type of semiconductor die that includes a specific subset of functionalities of an overall semiconductor device package. For example, a CPU device may include a plurality of chiplets that are packaged on a semiconductor package substrate. A chiplet may correspond to a logic die (e.g., a semiconductor die containing one or more processor cores), another chiplet may correspond to a memory die (e.g., a high bandwidth memory (HBM) die), and/or another chiplet may correspond to an input/output (I/O) die, among other examples. The chiplets may be electrically connected through redistribution layers in the semiconductor package substrate, and/or may be stacked in a system on integrated chips (SoIC) manner such that two or more chiplets are directly bonded and interconnected. Implementing chiplets on a semiconductor package substrate (e.g., as opposed to a monolithic die that includes the entire suite of functionalities) enables advancements to be realized for specific functionalities without having to necessarily redesign semiconductor dies for other functionalities.

FIG. 2A illustrates a top view of the semiconductor die 200. As shown in FIG. 2A, the semiconductor die 200 is manufactured on a semiconductor wafer 202 along with a plurality of other semiconductor dies. The semiconductor die 200 includes an active device region 204 and a periphery region 206 that surrounds the active device region 204 in the top view of the semiconductor die 200. The active device region 204 includes the active devices (e.g., active integrated circuitry) that provides the main functionality of the semiconductor die 200. The periphery region 206 provides a region around the perimeter of the semiconductor die 200 in which test pads are formed to enable wafer-level testing of the semiconductor die 200 prior to the semiconductor die 200 being diced from the semiconductor wafer 202.

The active device region 204 includes a plurality of redistribution pads 208 that enable electrical signals and/or power to be provided to and/or transferred from the semiconductor devices included in the active device region 204. The periphery region 206 includes a plurality of redistribution pads 210 that further enable electrical signals and/or power to be provided to and/or transferred from the semiconductor devices included in the active device region 204. The redistribution pads 210 may be electrically coupled with the active device region 204 through metallization layers 212. The metallization layers 212 enable electrical signals and/or power to be transferred between the active device region 204 and the periphery region 206, and/or are used for wafer-level testing of the semiconductor devices included in the active device region 204.

FIG. 2B illustrates a cross-sectional view of the active device region 204 and the periphery region 206 of the semiconductor die 200 along line A-A in FIG. 2A. As shown in FIG. 2B, the semiconductor die 200 includes a substrate 214. The substrate 214 corresponds to a portion of the semiconductor wafer 202 on which the semiconductor die 200 is formed. The substrate 214 includes a silicon (Si) substrate, a substrate formed of a material including silicon, a III-V compound semiconductor material substrate such as gallium arsenide (GaAs), a silicon on insulator (SOI) substrate, or another type of semiconductor substrate.

Semiconductor devices 216 are included in and/or on the substrate 214 in the active device region 204 of the semiconductor die 200. The semiconductor devices 216 include transistors (e.g., planar transistors, fin field effect transistors (finFETs), gate all around (GAA) transistors), pixel sensors, capacitors, resistors, inductors, photodetectors, transceivers, transmitters, receives, optical circuits, and/or other types of semiconductor devices.

A dielectric layer 218 is included over the substrate 214. The substrate, the semiconductor devices 216, and dielectric layer 218 may correspond to a front end of line (FEOL) region of the semiconductor die 200. The dielectric layer 218 includes an interlayer dielectric (ILD) layer, an etch stop layer (ESL), and/or another type of dielectric layer. The dielectric layer 218 includes dielectric material(s) that enable various portions of the substrate 214 and/or the semiconductor devices 216 to be selectively etched or protected from etching, and/or to electrically isolate the semiconductor devices 216 in the FEOL. The dielectric layers 218 includes a silicon nitride (SiₓN_{y}), an oxide (e.g., a silicon oxide (SiOₓ) and/or another oxide material), and/or another type of dielectric material.

A backend region 220 (e.g., a back end of line (BEOL) region) is included above the substrate 214 and above the semiconductor devices 216. In some implementations, one or more semiconductor devices 216 are included in the backend region 220 (e.g., a BEOL memory device, a BEOL resistor, a BEOL capacitor). The backend region 220 includes a plurality of dielectric layers that are arranged in a direction that is approximately perpendicular to the substrate 214. The dielectric layers may include ILD layers 222 and ESLs 224 that are arranged in an alternating manner. The ILD layers 222 and the ESLs 224 each include a silicon nitride (SiₓN_{y}), an oxide (e.g., a silicon oxide (SiOₓ) and/or another oxide material), and/or another type of dielectric material. In some implementations, an ILD layer 222 and an ESL 224 include different dielectric materials to provide etch selectivity to enable various structures to be formed in the backend region 220.

The backend region 220 includes a plurality of metallization layers 226 in the active device region 204. The metallization layers 226 are electrically coupled and/or physically coupled with one or more of the semiconductor devices 216 in the active device region 204. The metallization layers 226 correspond to circuitry that enables signals and/or power to be provided to and/or from the semiconductor devices 216. The backend region 220 further includes a plurality of metallization layers 212 in the periphery region 206. In some implementations, the metallization layers 212 enable signals and/or power to be provided to and/or from the semiconductor devices 216. In some implementations, the metallization layers 212 provide a seal ring around the perimeter of the semiconductor die 200, where the seal ring protects the active device region 204 from stresses and ingress of humidity and/or other contaminants. In some implementations, the metallization layers 212 provide test circuits that enable wafer-level testing to be performed on the semiconductor devices 216.

The metallization layers 212 and 226 each include vias, trenches, contacts, plugs, interconnects, and/or other types of conductive structures. The metallization layers 212 and 226 each include one or more electrically conductive materials such as tungsten (W), cobalt (Co), ruthenium (Ru), titanium (Ti), aluminum (Al), copper (Cu), gold (Au), and/or a combination thereof, among other examples of electrically conductive materials.

A top dielectric layer 228 is included above and/or over the backend region 220. The top dielectric layer 228 may be included for passivation of the backend region 220 and/or of the semiconductor devices 216 included in the active device region 204. The top dielectric layer 228 includes a silicon nitride (SiₓN_{y}), an oxide (e.g., a silicon oxide (SiOₓ) and/or another oxide material), and/or another type of dielectric material.

Metal pads 230 may be included over and/or on the metallization layers 226, and metal pads 232 may be included over and/or on the metallization layers 212. The metal pads 230 may be configured to transfer signals, voltage, currents, and/or other electrical inputs/outputs between the redistribution pads 208 on the top dielectric layer 228 and the metallization layers 226 in the active device region 204. The metal pads 232 may be configured to transfer signals, voltage, currents, and/or other electrical inputs/outputs between the redistribution pads 210 on the top dielectric layer 228 and the metallization layers 212 in the periphery region 206. The metal pads 230 and 232 each include aluminum (Al), aluminum copper (AlCu), tungsten (W), cobalt (Co), ruthenium (Ru), titanium (Ti), gold (Au), and/or another conductive material.

A barrier layer 234 is included under a redistribution pad 210. The barrier layer 234 is located between an inner portion of the redistribution pad 210 and the top dielectric layer 228. An outer portion of the redistribution pad 210 extends along the sides of the barrier layer 234 such that the barrier layer 234 is surrounded by the redistribution pad 210, and such that the outer portion is on the top dielectric layer 228. The barrier layer 234 is a remnant from a process for forming a test pad in the periphery region 206 prior to forming the redistribution pad 210 in place of the test pad after wafer-level testing is completed using the test pad. The barrier layer 234 is used to protect the top dielectric layer 228 from etching (e.g., from over etching) when etching a metal layer to form the test pad on the top dielectric layer 228.

The barrier layer 234 includes a material that is different from the material of the top dielectric layer 228. For example, the barrier layer 234 may include tantalum (Ta), tantalum nitride (TaN), titanium (Ti), and/or titanium nitride (TiN); and the top dielectric layer 228 may include a silicon oxide (SiOₓ such as SiO₂). The materials of the barrier layer 234 and the top dielectric layer 228 enable a wet etchant to be selected that is preferential to etching the material of the barrier layer 234, and is ineffective for etching the material of the top dielectric layer 228. In this way, the combination of materials selected for the barrier layer 234 and the top dielectric layer 228, and wet etchant selected for etching the barrier layer 234, enables a highly selective etch to be performed for etching the barrier layer 234, which results in minimal to no etching of the top dielectric layer 228.

Recesses 236 may be included in the top surface of the top dielectric layer 228. The recesses 236 may be located between adjacent redistribution pads 208, between adjacent redistribution pads 210, and/or between a redistribution pad 208 and an adjacent redistribution pad 210. The recesses 236 may result from etching of a metal layer to form the redistribution pads 208 and 210. Etching of the metal layer may result in over etching into the top dielectric layer 228.

FIG. 2C illustrates additional details of a redistribution pad 210 and an underlying barrier layer 234. As shown in FIG. 2C, the redistribution pad 210 includes a lower portion 238 on the top dielectric layer 228. The lower portion 238 of the redistribution pad 210 surrounds the barrier layer 234. The redistribution pad 210 further includes a raised portion 240 above the lower portion 238. The raised portion 240 is included directly over the barrier layer 234. The raised portion 240 extends above the lower portion 238 because of the redistribution pad 210 being formed on the barrier layer 234.

A first portion of a top surface of the top dielectric layer 228 under the lower portion 238, and a second portion of the top surface of the top dielectric layer 228 under the raised portion 240 (and under the barrier layer 234), are in a same plane (e.g., are co-planar). A bottom surface of the barrier layer 234 and a bottom surface of the lower portion 238 of the redistribution pad 210 are in a same plane (e.g., are co-planar). In other words, the top surface of the top dielectric layer 228 is flat under the redistribution pad 210 such that the top surface of the top dielectric layer 228 is in a same (singular) plane under the redistribution pad 210 between the edges or sides of the redistribution pad 210. This is in contrast to the top surface of the top dielectric layer 228 having a stepped profile (e.g., a profile with different heights), which might otherwise occur due to over etching into the top dielectric layer 228 if a non-selective etch technique (e.g., a dry etch technique, a plasma-based etch technique) were used to etch the barrier layer 234.

The barrier layer 234 includes recessed ends 242 between the barrier layer 234 and the lower portion 238 of the second redistribution pad 210. The recessed ends 242 have an inward curvature that results from wet etching of the barrier layer 234. In particular, the inward curvature occurs at the recessed ends 242 of the barrier layer 234 because of the isotropic etching that occurs during wet etching of the barrier layer 234.

FIGS. 2C and 2D illustrate one or more example dimensions of the semiconductor die 200. An example dimension D1 corresponds to a cross-sectional width of a redistribution pad 210. In some implementations, the dimension D1 is included in a range of approximately 30 nanometers to approximately 90 nanometers. Selecting the dimension D1 to be less than approximately 30 nanometers may result in insufficient contact area for the redistribution pad 210, resulting in reduced electrical conductivity and/or increased contact resistance. Selecting the dimension D1 to be greater than approximately 90 nanometers may result in reduced semiconductor die density on the semiconductor wafer 202. Selecting the dimension D1 to be approximately 30 nanometers to approximately 90 nanometers enables a sufficiently low contact resistance to be achieved for the redistribution pads 210 while enabling a sufficiently high semiconductor die density to be achieved for the semiconductor wafer 202. However, other values for the dimension D1, and ranges other than approximately 30 nanometers to approximately 90 nanometers, are within the scope of the present disclosure.

Another example dimension D2 corresponds to a cross-sectional width of a redistribution pad 208. In some implementations, the dimension D2 is included in a range of approximately 20 nanometers to approximately 80 nanometers. Selecting the dimension D2 to be less than approximately 20 nanometers may result in insufficient contact area for the redistribution pad 208, resulting in reduced electrical conductivity and/or increased contact resistance. Selecting the dimension D2 to be greater than approximately 80 nanometers may result in reduced semiconductor die density on the semiconductor wafer 202. Selecting the dimension D2 to be approximately 20 nanometers to approximately 80 nanometers enables a sufficiently low contact resistance to be achieved for the redistribution pads 208 while enabling a sufficiently high semiconductor die density to be achieved for the semiconductor wafer 202. However, other values for the dimension D2, and ranges other than approximately 20 nanometers to approximately 80 nanometers, are within the scope of the present disclosure.

Another example dimension D3 corresponds to a cross-sectional height or a cross-sectional thickness of a lower portion 238 of a redistribution pad 210. In some implementations, the dimension D3 is included in a range of approximately 30 nanometers to approximately 90 nanometers. Selecting the dimension D3 to be less than approximately 30 nanometers may result in insufficient rigidity and structural strength for the redistribution pad 210, increasing the likelihood of damage to the redistribution pad 210 when a wafer/die transport tool 116 (e.g., a pick and place tool) interfaces with the redistribution pad 210. Selecting the dimension D3 to be greater than approximately 90 nanometers may result in an unnecessary height increase of the semiconductor die 200. Selecting the dimension D3 to be approximately 30 nanometers to approximately 90 nanometers enables sufficient rigidity and structural strength to be achieved for the redistribution pad 210 while enabling a sufficiently low profile for the semiconductor die 200 to be achieved. However, other values for the dimension D3, and ranges other than approximately 30 nanometers to approximately 90 nanometers, are within the scope of the present disclosure.

Another example dimension D4 corresponds to a cross-sectional height or a cross-sectional thickness of a raised portion 240 of a redistribution pad 210. In some implementations, the dimension D4 is included in a range of approximately 10 nanometers to approximately 80 nanometers. Selecting the dimension D4 to be less than approximately 10 nanometers may result in an inability to form the redistribution pad 210 such that the height of the lower portion 238 (corresponding to the dimension D3) is included in a range of approximately 30 nanometers to approximately 90 nanometers. Selecting the dimension D4 to be greater than approximately 80 nanometers may result in too great of a difference in height between a top surface of a redistribution pad 208 and the top surface of the redistribution pad 210. In other words, selecting the dimension D4 to be greater than approximately 80 nanometers may result in too great of a height difference between the redistribution pad 208 and the redistribution pad 210, resulting in reduced effectiveness of a wafer/die transport tool 116 (e.g., a pick and place tool) for picking up the semiconductor die 200. In some cases, selecting the dimension D4 to be greater than approximately 80 nanometers may result in the wafer/die transport tool 116 being unable to pick up the semiconductor die 200. Selecting the dimension D4 to be approximately 10 nanometers to approximately 80 nanometers enables sufficient rigidity and structural strength to be achieved for the redistribution pad 210 while enabling a sufficiently low height difference between the redistribution pad 208 and the redistribution pad 210 to be achieved. However, other values for the dimension D4, and ranges other than approximately 10 nanometers to approximately 80 nanometers, are within the scope of the present disclosure.

Another example dimension D5 corresponds to a cross-sectional height or a cross-sectional thickness of a redistribution pad 210. In particular, the dimension D5 corresponds to a combined cross-sectional height or a combined cross-sectional thickness of a lower portion 238 and a raised portion 240 of the redistribution pad 210. In some implementations, the dimension D5 is included in a range of approximately 40 nanometers to approximately 170 nanometers. Selecting the dimension D5 to be less than approximately 40 nanometers or greater than approximately 170 nanometers may result in too great of a difference in height between a top surface of a redistribution pad 208 and the top surface of the redistribution pad 210, resulting in reduced effectiveness of a wafer/die transport tool 116 (e.g., a pick and place tool) for picking up the semiconductor die 200. Selecting the dimension D5 to be approximately 40 nanometers to approximately 170 nanometers enables a sufficiently low height difference between the redistribution pad 208 and the redistribution pad 210 to be achieved. However, other values for the dimension D5, and ranges other than approximately 40 nanometers to approximately 170 nanometers, are within the scope of the present disclosure.

Another example dimension D6 corresponds to a cross-sectional height or a cross-sectional thickness of a redistribution pad 208. In some implementations, the dimension D3 and the dimension D6 may be approximately a same value since the redistribution pads 208 and 210 may be formed from the same metal layer. In some implementations, the dimension D6 is included in a range of approximately 30 nanometers to approximately 90 nanometers. Selecting the dimension D6 to be less than approximately 30 nanometers or greater than approximately 90 nanometers may result in too great of a difference in height between a top surface of a redistribution pad 208 and the top surface of the redistribution pad 210, resulting in reduced effectiveness of a wafer/die transport tool 116 (e.g., a pick and place tool) for picking up the semiconductor die 200. Selecting the dimension D6 to be approximately 30 nanometers to approximately 90 nanometers enables a sufficiently low height difference between the redistribution pad 208 and the redistribution pad 210 to be achieved. However, other values for the dimension D6, and ranges other than approximately 30 nanometers to approximately 90 nanometers, are within the scope of the present disclosure.

Another example dimension D7 corresponds to a cross-sectional depth of a recess 236 in the top dielectric layer 228. In some implementations, the dimension D7 is included in a range of approximately 20 nanometers to approximately 80 nanometers. However, other values for the dimension D7, and ranges other than approximately 20 nanometers to approximately 80 nanometers, are within the scope of the present disclosure.

Another example dimension D8 corresponds to a cross-sectional width of the barrier layer 234. In some implementations, the dimension D8 is included in a range of approximately 20 nanometers to approximately 80 nanometers. As described in connection with FIGS. 4A-4M, the cross-sectional width may correspond to a cross-sectional width of a test pad that is formed above the barrier layer 234 in the periphery region 206. Selecting the dimension D8 to be less than approximately 20 nanometers may result in test pads that are too small and have too high of electrical resistance to enable accurate test measurements to be performed. Selecting the dimension D8 to be greater than approximately 80 nanometers may result in too low of density of test pads in the periphery region 206. However, other values for the dimension D8, and ranges other than approximately 20 nanometers to approximately 80 nanometers, are within the scope of the present disclosure.

Another example dimension D8 corresponds to a cross-sectional width of the barrier layer 234. In some implementations, the dimension D8 is included in a range of approximately 20 nanometers to approximately 80 nanometers. As described in connection with FIGS. 4A-4M, the cross-sectional width may correspond to a cross-sectional width of a test pad that is formed above the barrier layer 234 in the periphery region 206. Selecting the dimension D8 to be less than approximately 20 nanometers may result in test pads that are too small and have too high of electrical resistance to enable accurate test measurements to be performed. Selecting the dimension D8 to be greater than approximately 80 nanometers may result in too low of density of test pads in the periphery region 206. Selecting the dimension D8 to be approximately 20 nanometers to approximately 80 nanometers enables a sufficient test pad density to be achieved in the periphery region 206, while achieving a sufficiently low electrical resistance for the test pads. However, other values for the dimension D8, and ranges other than approximately 20 nanometers to approximately 80 nanometers, are within the scope of the present disclosure.

Another example dimension D9 corresponds to a cross-sectional thickness of the barrier layer 234. In some implementations, the dimension D9 is included in a range of approximately 20 nanometers to approximately 80 nanometers. Selecting the dimension D9 to be less than approximately 20 nanometers may result in the barrier layer 234 being too thin to provide sufficient etch stopping when etching test pads in the periphery region 206. Selecting the dimension D9 to be greater than approximately 80 nanometers may result in too great of a difference in height between a top surface of a redistribution pad 208 and a top surface of a redistribution pad 210, resulting in reduced effectiveness of a wafer/die transport tool 116 (e.g., a pick and place tool) for picking up the semiconductor die 200. Selecting the dimension D9 to be approximately 20 nanometers to approximately 80 nanometers enables a sufficiently low height difference between the redistribution pad 208 and the redistribution pad 210 to be achieved while enabling the barrier layer 234 to provide sufficient etch stopping when etching the test pads in the periphery region 206. However, other values for the dimension D9, and ranges other than approximately 20 nanometers to approximately 80 nanometers, are within the scope of the present disclosure.

Another example dimension D10 corresponds to a lateral depth of a recessed end 242 of the barrier layer 234. In some implementations, the dimension D10 is included in a range of approximately 10 nanometers to approximately 80 nanometers. However, other values for the dimension D10, and ranges other than approximately 10 nanometers to approximately 80 nanometers, are within the scope of the present disclosure.

As shown in FIG. 2D, another example dimension D11 corresponds to a height difference between a height of a top surface of a redistribution pad 208 and a height of a top surface of a raised portion 240 of a redistribution pad 210. In some implementations, the dimension D11 is included in a range of approximately 10 nanometers to approximately 80 nanometers. Selecting the dimension D11 to be less than approximately 10 nanometers may result in the barrier layer 234 being too thin to provide sufficient etch stopping when etching test pads in the periphery region 206. Selecting the dimension D11 to be greater than approximately 80 nanometers may result in too great of a difference in height between the top surface of a redistribution pad 208 and the top surface of the raised portion 240 of the redistribution pad 210, resulting in reduced effectiveness of a wafer/die transport tool 116 (e.g., a pick and place tool) for picking up the semiconductor die 200. In some cases, selecting the dimension D11 to be greater than approximately 80 nanometers may result in the wafer/die transport tool 116 being unable to pick up the semiconductor die 200. Selecting the dimension D11 to be approximately 10 nanometers to approximately 80 nanometers enables a sufficiently low height difference between the redistribution pad 208 and the redistribution pad 210 to be achieved while enabling the barrier layer 234 to provide sufficient etch stopping when etching the test pads in the periphery region 206. However, other values for the dimension D11, and ranges other than approximately 10 nanometers to approximately 80 nanometers, are within the scope of the present disclosure.

As indicated above, FIGS. 2A-2D are provided as an example. Other examples may differ from what is described with regard to FIGS. 2A-2D.

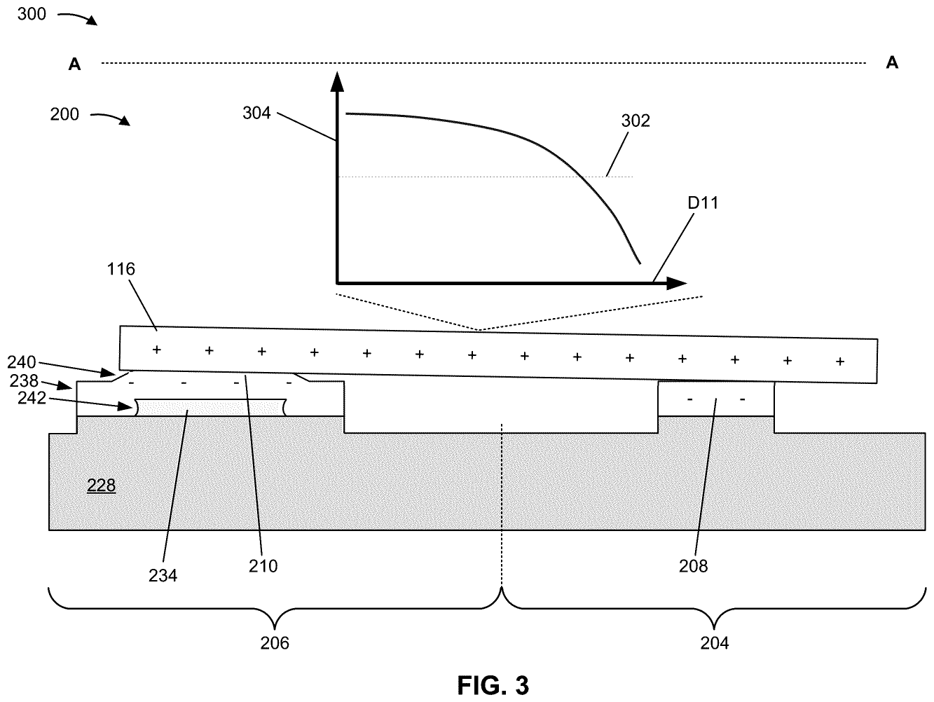

FIG. 3 is a diagram of an example implementation 300 of picking up a semiconductor die 200 using a wafer/die transport tool 116 (e.g., a pick and place tool) described herein. As shown in FIG. 3, the wafer/die transport tool 116 may be used to pick up the semiconductor die 200 using an electric and/or magnetic force between the wafer/die transport tool 116 and the redistribution pads 208 and 210 of the semiconductor die 200. The wafer/die transport tool 116 may be biased with a positive electrical or magnetic bias, and the redistribution pads 208 and 210 may be biased with a negative electrical or magnetic bias (e.g., because of the metal material(s) of the redistribution pads 208 and 210). The electric and/or magnetic force between the wafer/die transport tool 116 and the redistribution pads 208 and 210 causes an attraction force to secure the semiconductor die 200 against the wafer/die transport tool 116. The positive electrical or magnetic bias may be removed from the wafer/die transport tool 116 to release the electric and/or magnetic force on the semiconductor die 200 so that the semiconductor die 200 may be placed on a semiconductor package substrate, on a printed circuit board, and/or on another surface.

As further shown in FIG. 3, a threshold 302 for a normalized force 304 between the wafer/die transport tool 116 and the redistribution pads 208 and 210 may be used to determine whether the wafer/die transport tool 116 can apply a sufficient amount of electric and/or magnetic force to the redistribution pads 208 and 210 to successfully pick up the semiconductor die 200. The step height (corresponding to the dimension D11) being within the range of approximately 10 nanometers to approximately 80 nanometers may enable a sufficient amount of electric and/or magnetic force to be applied to the redistribution pads 208 and 210 to satisfy the threshold 302. If the step height is too great, the angle of the wafer/die transport tool 116 may be too steep, which reduces the contact surface area between the wafer/die transport tool 116 and the redistribution pads 208 and 210, which may prevent the wafer/die transport tool 116 from applying a sufficient amount of electric and/or magnetic force to the redistribution pads 208 and 210. The step height being within the range of approximately 10 nanometers to approximately 80 nanometers provides a sufficient amount of contact surface area between the wafer/die transport tool 116 and the redistribution pads 208 and 210 to enable the wafer/die transport tool 116 to apply a sufficient amount of electric and/or magnetic force to the redistribution pads 208 and 210 to successfully pick up the semiconductor die 200.

As indicated above, FIG. 3 is provided as an example. Other examples may differ from what is described with regard to FIG. 3.

FIGS. 4A-4M are diagrams of an example implementation 400 of forming the semiconductor die 200 described herein. In some implementations, one or more of the semiconductor processing tools 102-114 and/or the wafer/die transport tool 116 may be used to perform one or more of the semiconductor processing operations described in connection with FIGS. 4A-4M. In some implementations, one or more of the semiconductor processing operations described in connection with FIGS. 4A-4M may be performed using another semiconductor processing tool.

Turning to FIG. 4A, the substrate 214 may be provided. The substrate 214 may be provided in the form of a semiconductor wafer such as a silicon (Si) wafer. The semiconductor die 200 may be formed on the substrate 214 along with a plurality of other semiconductor dies 200.

As shown in FIG. 4B, the semiconductor devices 216 may be formed in and/or on the substrate 214 in the active device region 204 of the semiconductor die 200. One or more of the semiconductor processing tools 102-114 may be used to form one or more portions of the semiconductor devices 216. For example, a deposition tool 102 may be used to perform various deposition operations to deposit layers of the semiconductor devices 216, and/or to deposit photoresist layers for etching the substrate 214 and/or portions of the deposited layers. As another example, an exposure tool 104 may be used to expose the photoresist layers to form patterns in the photoresist layers. As another example, a developer tool 106 may develop the patterns in the photoresist layers. As another example, an etch tool 108 may be used to etch the substrate 214 and/or portions of the deposited layers to form the semiconductor devices 216. As another example, a planarization tool 110 may be used to planarize portions of the semiconductor devices 216. As another example, a plating tool 112 may be used to deposit metal structures and/or layers of the semiconductor devices 216.

As shown in FIG. 4C, a deposition tool 102 is used to deposit the dielectric layer 218 over and/or on the substrate 214 and over and/or on the semiconductor devices 216. A deposition tool 102 is also used to deposit alternating layers of ESLs 224 and ILD layers 222 of the backend region 220 of the semiconductor die 200. A deposition tool 102, an exposure tool 104, a developer tool 106, an etch tool 108, a planarization tool 110, and/or a plating tool 112 are used to perform various operations to form the metallization layers 212 and metal pads 232 in the periphery region 206 of the semiconductor die 200, and to form the metallization layers 226 and the metal pads 230 in the active device region 204 of the semiconductor die 200. The metallization layers 226 may be electrically coupled with the semiconductor devices 216.

As further shown in FIG. 4C, the top dielectric layer 228 is formed over and/or on the backend region 220 of the semiconductor die 200. A deposition tool 102 may be used to deposit the top dielectric layer 228 using a PVD technique, an ALD technique, a CVD technique, an oxidation technique, another type of deposition technique described in connection with FIG. 1, and/or another suitable deposition technique. In some implementations, the planarization tool 110 may be used to planarize the top dielectric layer 228 after the top dielectric layer 228 is deposited.

As shown in FIG. 4D, the barrier layer 234 is formed over and/or on the top dielectric layer 228. A deposition tool 102 and/or a plating tool 112 may be used to deposit the barrier layer 234 using a PVD technique, an ALD technique, a CVD technique, an oxidation technique, an electroplating technique, another type of deposition technique described in connection with FIG. 1, and/or another suitable deposition technique. In some implementations, the planarization tool 110 may be used to planarize the barrier layer 234 after the barrier layer 234 is deposited.

As further shown in FIG. 4D, a metal layer 402 is formed over and/or on the barrier layer 234. A deposition tool 102 and/or a plating tool 112 may be used to deposit the metal layer 402 using a PVD technique, an ALD technique, a CVD technique, an oxidation technique, an electroplating technique, another type of deposition technique described in connection with FIG. 1, and/or another suitable deposition technique. In some implementations, the planarization tool 110 may be used to planarize the metal layer 402 after the metal layer 402 is deposited. In some implementations, a seed layer is first deposited, and the metal layer 402 is deposited on the seed layer. The metal layer 402 includes aluminum (Al), aluminum copper (AlCu), tungsten (W), cobalt (Co), ruthenium (Ru), titanium (Ti), gold (Au), and/or another conductive material.

As further shown in FIG. 4D, a capping layer 404 is formed over and/or on the metal layer 402. A deposition tool 102 may be used to deposit the capping layer 404 using a PVD technique, an ALD technique, a CVD technique, an oxidation technique, another type of deposition technique described in connection with FIG. 1, and/or another suitable deposition technique. In some implementations, the planarization tool 110 may be used to planarize the capping layer 404 after the capping layer 404 is deposited. The capping layer 404 includes silicon nitride (SiₓN_{y}), silicon oxynitride (SiON), and/or another suitable capping material. The capping layer 404 may be used to protect a portion of the metal layer 402 from etching to enable a test pad to be formed from the metal layer 402.

As shown in FIGS. 4E and 4F, a pattern in a photoresist layer 406 is used to etch the capping layer 404 and the metal layer 402 to form a test pad 408 in the periphery region 206 of the semiconductor die 200. The test pad 408 may be formed above the top dielectric layer 228 by removing portions of the metal layer 402 using the pattern in the photoresist layer 406, where a remaining portion of the metal layer 402 corresponds to the test pad 408. In these implementations, a deposition tool 102 is used to form the photoresist layer 406 on the capping layer 404. An exposure tool 104 is used to expose the photoresist layer 406 to a radiation source to pattern the photoresist layer 406. A developer tool 106 is used to develop and remove portions of the photoresist layer 406 to expose the pattern. An etch tool 108 may be used to etch the capping layer 404 and the metal layer 402 based on the pattern in the photoresist layer 406 to form the test pad 408 from the metal layer 402. The etch operation stops on the barrier layer 234 (meaning that the etch operation does not continue through the barrier layer 234). In some implementations, the etch operation includes a dry etch operation such as a plasma-based etch operation. The dry etch operation may enable an anisotropic etch to be performed to form the test pad 408 such that the test pad 408 has substantially vertical sidewalls. However, other etch techniques for forming the test pad 408 are within the scope of the present disclosure. In some implementations, a photoresist removal tool may be used to remove the remaining portions of the photoresist layer (e.g., using a chemical stripper, plasma ashing, and/or another technique). In some implementations, a hard mask layer is used as an alternative technique for etching the metal layer 402 based on a pattern.

As shown in FIG. 4G, a dielectric layer 410 is formed over and/or on the barrier layer 234. Moreover, the dielectric layer 410 is conformally deposited on sidewalls of the test pad 408 and on the remaining portion of the capping layer 404 over the test pad 408. A deposition tool 102 may be used to deposit the dielectric layer 410 using a PVD technique, an ALD technique, a CVD technique, an oxidation technique, another type of deposition technique described in connection with FIG. 1, and/or another suitable deposition technique.

As shown in FIG. 4H, the dielectric layer 410 may be etched to remove portions of the dielectric layer 410 from on the barrier layer 234 and from on the capping layer 404. The remaining portions of the dielectric layer 410 correspond to sidewall spacers 412 that are formed on the sidewalls of the test pad 408. An etch tool 108 may be used to perform an etch operation to etch the dielectric layer 410 to form the sidewall spacers 412. The etch operation may be a self-aligned etch operation in which the capping layer 404 is used as a self-aligned hard mask that protects the test pad 408 from being etched during the etch operation. Moreover, the etch operation may include a dry etch operation such as a plasma-based etch operation. This enables the etch operation to be anisotropic, which results in a vertical etching direction for the etch operation. Thus, the dielectric layer 410 is removed from horizontal surfaces of the semiconductor die 200 and remains on the vertical sidewalls of the test pad 408. The tops of the sidewall spacers 412 may be rounded or curved as a result of the etch operation.

As shown in FIG. 4I, another etch operation is performed to remove portions of the barrier layer 234 that are not under the test pad 408 and that are not under the sidewall spacers 412. The sidewall spacers 412 and the capping layer 404 protect the test pad 408 from being etched during the etch operation. This etch operation results in the top dielectric layer 228 being exposed. The etch operation includes a wet etch operation, in which a highly selective wet etch technique is used to etch a barrier layer 234. The wet etch technique involves the use of a wet etchant that has a high etch rate for the barrier layer 234 and a very low etch rate (effectively a zero etch rate, in some cases) for the top dielectric layer 228. As an example, a wet etchant may be selected for the etch operation such that an etch rate for the tantalum nitride (TaN) of the barrier layer 234 in the etch operation is approximately 125 angstroms per minute or greater, whereas an etch rate for the oxide material of the top dielectric layer 228 in the etch operation is approximately 0 angstroms per minute. In this way, the etch operation stops on the top dielectric layer 228 such that the top dielectric layer 228 is not etched (or a minimal amount of etching of the top dielectric layer 228 occurs) during the etch operation.

In some implementations, the wet etchant has a high etch rate for nitride materials and a low etch rate for oxide materials. In some implementations, the wet etchant includes a combination of ammonium hydroxide (NH₄OH), hydrogen peroxide (H₂O₂), and water (H₂O). The hydrogen peroxide may be a greater concentration by weight of the wet etchant than the ammonium hydroxide. For example, a ratio of ammonium hydroxide to hydrogen peroxide to water in the wet etchant may be approximately 1:4:20 to approximately 1:8:60. However, other values for the range are within the scope of the present disclosure. The ammonium hydroxide, hydrogen peroxide, and water may be used to etch the barrier layer 234 at a temperature that is included in a range of approximately 40 degrees Celsius to approximately 80 degrees Celsius. However, other values for the range are within the scope of the present disclosure.

In some implementations, the wet etchant includes a hydrochloric acid (HCl) and nitric acid (HNO₃). The hydrochloric acid may be a greater concentration by weight of the wet etchant than the nitric acid. For example, a ratio of hydrochloric acid to nitric acid in the wet etchant may be approximately 3:1 to approximately 5:1. However, other values for the range are within the scope of the present disclosure. The hydrochloric acid and the nitric acid may be used to etch the barrier layer 234 at a temperature that is included in a range of approximately 20 degrees Celsius to approximately 80 degrees Celsius. However, other values for the range are within the scope of the present disclosure.

As further shown in FIG. 4I, the recessed ends 242 are formed in the ends of the barrier layer 234. The wet etch technique that is used to etch the barrier layer 234 is an isotropic etch technique. Accordingly, some lateral etching occurs in the ends of the barrier layer 234, resulting in formation of the recessed ends 242 in the barrier layer 234. Moreover, the etch operation stopping on the top dielectric layer 228 such that the top dielectric layer 228 is not etched (or a minimal amount of etching of the top dielectric layer 228 occurs) during the etch operation results in the bottom surface of the barrier layer 234 and the top surface of the top dielectric layer 228 remaining co-planar.

After formation of the test pads 408 in the periphery region 206, the metallization layers 212 are used as test circuits for wafer-level testing of one or more parameters of the semiconductor die 200. In other words, the test pads 408 in the periphery region 206 and the metallization layers 212 may be used to perform wafer-level testing of the semiconductor die 200 prior to the semiconductor wafer on which the semiconductor die 200 is formed is diced into individual semiconductor dies. The wafer testing tool 114 may be used to provide test inputs to the metallization layers 212 through the test pads 408, and/or to perform measurements associated with the one or more parameters through the test pads 408. The one or more parameters may include current leakage in the active device region 204, parasitic capacitance in the active device region 204, electrical resistance in the active device region 204, a transistor gate voltage in the active device region 204, a breakdown voltage in the active device region 204, a power consumption of the semiconductor devices 216 in the active device region 204, and/or another parameter. In some implementations, the metallization layers 212 are used as test circuits for wafer-level testing of over-current protection for the semiconductor devices 216 in the active device region 204, for wafer-level testing of over-voltage protection for the semiconductor devices 216 in the active device region 204, for wafer-level testing of over-current protection for the semiconductor devices 216 in the active device region 204, for wafer-level testing of continuity of one or more of the metallization layers 226, and/or another functionality of the semiconductor die 200.

As shown in FIG. 4J, the test pad 408 (and the capping layer 404 and the sidewall spacers 412 on the test pad 408) may be removed after the wafer-level testing for the semiconductor die 200 is completed. In some implementations, an etch tool 108 is used to remove the capping layer 404, the test pad 408, and/or the sidewall spacers 412. In some implementations, a planarization tool 110 is used to perform a CMP operation to remove the capping layer 404, the test pad 408, and/or the sidewall spacers 412. In some implementations, a grinding tool is used to perform a grinding operation to remove the capping layer 404, the test pad 408, and/or the sidewall spacers 412. As further shown in FIG. 4J, the barrier layer 234 that was under the test pad 408 remains on the top dielectric layer 228.

As shown in FIG. 4K, a metal layer 414 is formed over and/or on the top dielectric layer 228 and over and/or on the barrier layer 234. A deposition tool 102 and/or a plating tool 112 may be used to deposit the metal layer 414 using a CVD technique, a PVD technique, an ALD technique, an electroplating technique, another deposition technique described above in connection with FIG. 1, and/or another suitable deposition technique. In some implementations, a seed layer is first deposited, and the metal layer 414 is deposited on the seed layer. The metal layer 414 includes aluminum (Al), aluminum copper (AlCu), tungsten (W), cobalt (Co), ruthenium (Ru), titanium (Ti), gold (Au), and/or another conductive material.

As shown in FIGS. 4L and 4M, a pattern in a photoresist layer 416 is used to etch the metal layer 414 to form the redistribution pads 208 in the active device region 204, and to form the redistribution pads 210 in the periphery region 206 of the semiconductor die 200. A redistribution pad 210 is formed over the barrier layer 234 in place of a test pad 408 that was removed from the periphery region 206. The redistribution pads 208 and 210 may be formed above the top dielectric layer 228 by removing portions of the metal layer 414 using the pattern in the photoresist layer 416, where remaining portions of the metal layer 414 correspond to the redistribution pads 208 and 210. In these implementations, a deposition tool 102 is used to form the photoresist layer 416 on the metal layer 414. An exposure tool 104 is used to expose the photoresist layer 416 to a radiation source to pattern the photoresist layer 416. A developer tool 106 is used to develop and remove portions of the photoresist layer 416 to expose the pattern. An etch tool 108 may be used to etch the metal layer 414 based on the pattern in the photoresist layer 416 to form the redistribution pads 208 and 210. The etch operation may include a dry etch operation such as a plasma-based etch operation. The dry etch operation may enable an anisotropic etch to be performed to form the redistribution pads 208 and 210 such that the redistribution pads 208 and 210 have substantially vertical sidewalls. However, other etch techniques for forming the redistribution pads 208 and 210 are within the scope of the present disclosure. In some implementations, a photoresist removal tool may be used to remove the remaining portions of the photoresist layer (e.g., using a chemical stripper, plasma ashing, and/or another technique). In some implementations, a hard mask layer is used as an alternative technique for etching the metal layer 414 based on a pattern.

As further shown in FIG. 4M, etching the metal layer 414 to form the redistribution pads 208 and 210 may result in over etching into the top dielectric layer 228. The over etching results in formation of the recesses 236.

As indicated above, FIGS. 4A-4M are provided as an example. Other examples may differ from what is described with regard to FIGS. 4A-4M.

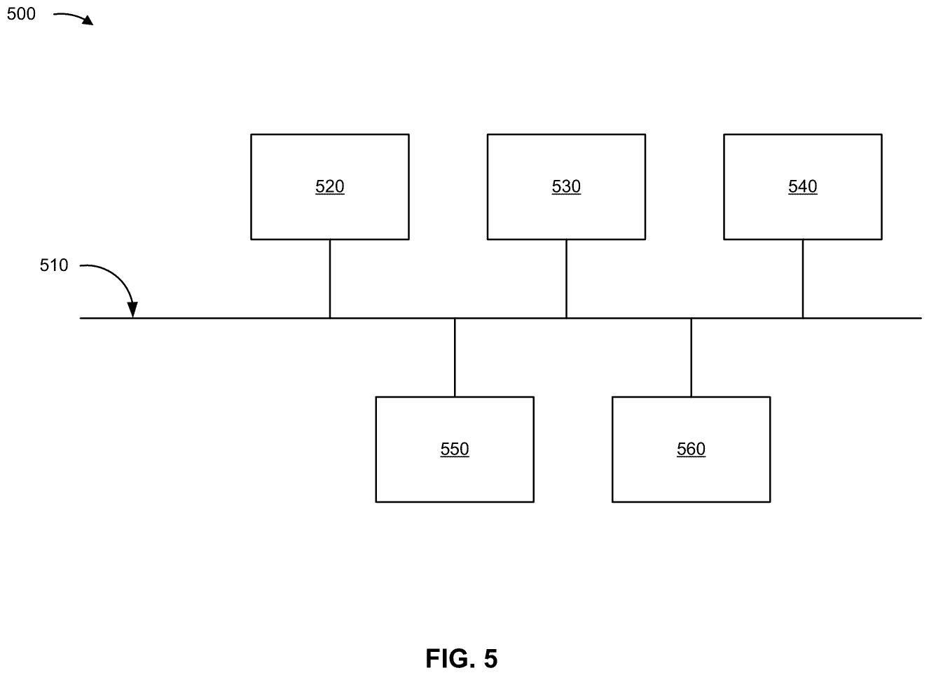

FIG. 5 is a diagram of example components of a device 500 described herein. In some implementations, one or more of the semiconductor processing tools 102-114 and/or the wafer/die transport tool 116 may include one or more devices 500 and/or one or more components of the device 500. As shown in FIG. 5, the device 500 may include a bus 510, a processor 520, a memory 530, an input component 540, an output component 550, and/or a communication component 560.

The bus 510 may include one or more components that enable wired and/or wireless communication among the components of the device 500. The bus 510 may couple together two or more components of FIG. 5, such as via operative coupling, communicative coupling, electronic coupling, and/or electric coupling. For example, the bus 510 may include an electrical connection (e.g., a wire, a trace, and/or a lead) and/or a wireless bus. The processor 520 may include a central processing unit, a graphics processing unit, a microprocessor, a controller, a microcontroller, a digital signal processor, a field-programmable gate array, an application-specific integrated circuit, and/or another type of processing component. The processor 520 may be implemented in hardware, firmware, or a combination of hardware and software. In some implementations, the processor 520 may include one or more processors capable of being programmed to perform one or more operations or processes described elsewhere herein.

The memory 530 may include volatile and/or nonvolatile memory. For example, the memory 530 may include random access memory (RAM), read only memory (ROM), a hard disk drive, and/or another type of memory (e.g., a flash memory, a magnetic memory, and/or an optical memory). The memory 530 may include internal memory (e.g., RAM, ROM, or a hard disk drive) and/or removable memory (e.g., removable via a universal serial bus connection). The memory 530 may be a non-transitory computer-readable medium. The memory 530 may store information, one or more instructions, and/or software (e.g., one or more software applications) related to the operation of the device 500. In some implementations, the memory 530 may include one or more memories that are coupled (e.g., communicatively coupled) to one or more processors (e.g., processor 520), such as via the bus 510. Communicative coupling between a processor 520 and a memory 530 may enable the processor 520 to read and/or process information stored in the memory 530 and/or to store information in the memory 530.

The input component 540 may enable the device 500 to receive input, such as user input and/or sensed input. For example, the input component 540 may include a touch screen, a keyboard, a keypad, a mouse, a button, a microphone, a switch, a sensor, a global positioning system sensor, a global navigation satellite system sensor, an accelerometer, a gyroscope, and/or an actuator. The output component 550 may enable the device 500 to provide output, such as via a display, a speaker, and/or a light-emitting diode. The communication component 560 may enable the device 500 to communicate with other devices via a wired connection and/or a wireless connection. For example, the communication component 560 may include a receiver, a transmitter, a transceiver, a modem, a network interface card, and/or an antenna.

The device 500 may perform one or more operations or processes described herein. For example, a non-transitory computer-readable medium (e.g., memory 530) may store a set of instructions (e.g., one or more instructions or code) for execution by the processor 520. The processor 520 may execute the set of instructions to perform one or more operations or processes described herein. In some implementations, execution of the set of instructions, by one or more processors 520, causes the one or more processors 520 and/or the device 500 to perform one or more operations or processes described herein. In some implementations, hardwired circuitry may be used instead of or in combination with the instructions to perform one or more operations or processes described herein. Additionally, or alternatively, the processor 520 may be configured to perform one or more operations or processes described herein. Thus, implementations described herein are not limited to any specific combination of hardware circuitry and software.

The number and arrangement of components shown in FIG. 5 are provided as an example. The device 500 may include additional components, fewer components, different components, or differently arranged components than those shown in FIG. 5. Additionally, or alternatively, a set of components (e.g., one or more components) of the device 500 may perform one or more functions described as being performed by another set of components of the device 500.

FIG. 6 is a flowchart of an example process 600 associated with forming a semiconductor die described herein. In some implementations, one or more process blocks of FIG. 6 are performed using one or more semiconductor processing tools (e.g., one or more of the semiconductor processing tools 102-114). Additionally, or alternatively, one or more process blocks of FIG. 6 may be performed using one or more components of device 500, such as processor 520, memory 530, input component 540, output component 550, and/or communication component 560.

As shown in FIG. 6, process 600 may include forming one or more semiconductor devices in an active device region of a semiconductor die (block 605). For example, one or more of the semiconductor processing tools 102-114 may be used to form one or more semiconductor devices 216 in an active device region 204 of a semiconductor die 200, as described herein.

As further shown in FIG. 6, process 600 may include forming one or more first metallization layers in a backend region above the one or more semiconductor devices (block 610). For example, one or more of the semiconductor processing tools 102-114 may be used to form one or more first metallization layers 226 in a backend region 220 above the one or more semiconductor devices 216, as described herein.

As further shown in FIG. 6, process 600 may include forming one or more second metallization layers in the backend region in a periphery region of the semiconductor die (block 615). For example, one or more of the semiconductor processing tools 102-114 may be used to form one or more second metallization layers 212 in the backend region 220 in a periphery region 206 of the semiconductor die 200, as described herein. In some implementations, the periphery region 206 surrounds the active device region 204 in a top view of the semiconductor die 200.

As further shown in FIG. 6, process 600 may include forming a top dielectric layer above the backend region after forming the one or more first metallization layers and the one or more second metallization layers (block 620). For example, one or more of the semiconductor processing tools 102-114 may be used to form a top dielectric layer 228 above the backend region 220 after forming the one or more first metallization layers 226 and the one or more second metallization layers 212, as described herein.

As further shown in FIG. 6, process 600 may include forming a barrier layer on the top dielectric layer (block 625). For example, one or more of the semiconductor processing tools 102-114 may be used to form a barrier layer 234 on the top dielectric layer 228, as described herein.

As further shown in FIG. 6, process 600 may include forming a metal layer on the barrier layer (block 630). For example, one or more of the semiconductor processing tools 102-114 may be used to form a metal layer 402 on the barrier layer 234, as described herein.

As further shown in FIG. 6, process 600 may include forming a capping layer on the metal layer (block 635). For example, one or more of the semiconductor processing tools 102-114 may be used to form a capping layer 404 on the metal layer 402, as described herein.

As further shown in FIG. 6, process 600 may include performing a first etch operation to etch the capping layer and the metal layer to form a test pad on the top dielectric layer in the periphery region (block 640). For example, one or more of the semiconductor processing tools 102-114 may be used to perform a first etch operation to etch the capping layer 404 and the metal layer 402 to form a test pad 408 on the top dielectric layer 228 in the periphery region 206, as described herein.

As further shown in FIG. 6, process 600 may include performing, after the first etch operation, a second etch operation to etch the barrier layer such that the barrier layer remains only under the test pad (block 645). For example, one or more of the semiconductor processing tools 102-114 may be used to perform, after the first etch operation, a second etch operation to etch the barrier layer 234 such that the barrier layer 234 remains only under the test pad 408, as described herein.

Process 600 may include additional implementations, such as any single implementation or any combination of implementations described below and/or in connection with one or more other processes described elsewhere herein.

In a first implementation, the second etch operation includes a wet etch operation using a wet etchant.

In a second implementation, alone or in combination with the first implementation, the wet etchant includes a combination of ammonium hydroxide (NH₄OH), hydrogen peroxide (H₂O₂), and water (H₂O).

In a third implementation, alone or in combination with one or more of the first and second implementations, the hydrogen peroxide includes a greater concentration by weight of the wet etchant than the ammonium hydroxide.

In a fourth implementation, alone or in combination with one or more of the first through third implementations, the wet etchant includes a combination of hydrochloric acid (HCl) and nitric acid (HNO₃).

In a fifth implementation, alone or in combination with one or more of the first through fourth implementations, the hydrochloric acid includes a greater concentration by weight of the wet etchant than the nitric acid.

In a sixth implementation, alone or in combination with one or more of the first through fifth implementations, an etch rate of the wet etchant for the barrier layer 234 is greater than an etch rate of the wet etchant for the top dielectric layer 228.

In a seventh implementation, alone or in combination with one or more of the first through sixth implementations, the second etch operation stops on the top dielectric layer 228.

Although FIG. 6 shows example blocks of process 600, in some implementations, process 600 includes additional blocks, fewer blocks, different blocks, or differently arranged blocks than those depicted in FIG. 6. Additionally, or alternatively, two or more of the blocks of process 600 may be performed in parallel.

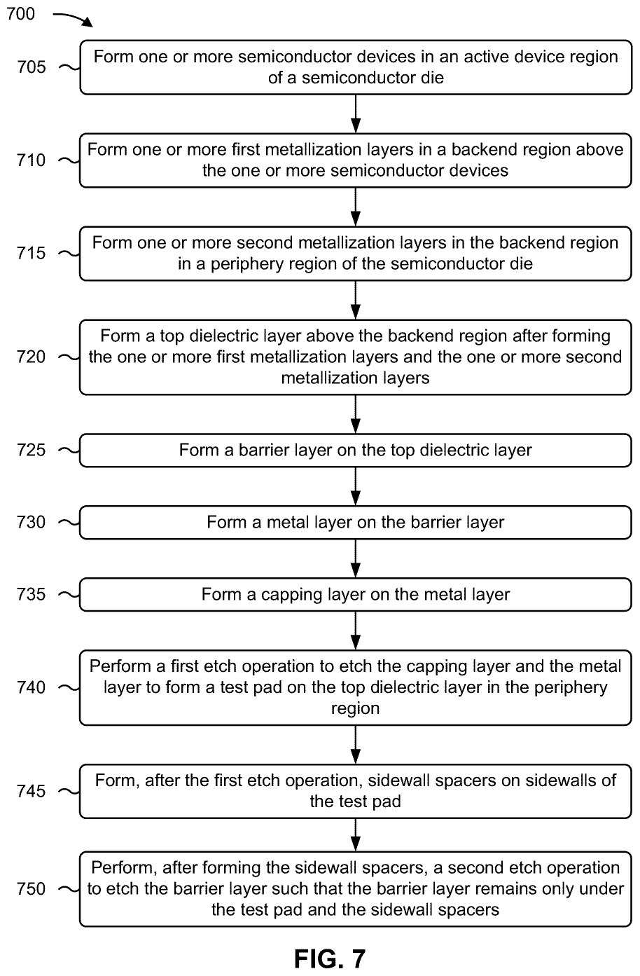

FIG. 7 is a flowchart of an example process 700 associated with forming a semiconductor die described herein. In some implementations, one or more process blocks of FIG. 7 are performed using one or more semiconductor processing tools (e.g., one or more of the semiconductor processing tools 102-114). Additionally, or alternatively, one or more process blocks of FIG. 7 may be performed using one or more components of device 500, such as processor 520, memory 530, input component 540, output component 550, and/or communication component 560.

As shown in FIG. 7, process 700 may include forming one or more semiconductor devices in an active device region of a semiconductor die (block 705). For example, one or more of the semiconductor processing tools 102-114 may be used to form one or more semiconductor devices 216 in an active device region 204 of a semiconductor die 200, as described herein.

As further shown in FIG. 7, process 700 may include forming one or more first metallization layers in a backend region above the one or more semiconductor devices (block 710). For example, one or more of the semiconductor processing tools 102-114 may be used to form one or more first metallization layers 226 in a backend region 220 above the one or more semiconductor devices 216, as described herein.

As further shown in FIG. 7, process 700 may include forming one or more second metallization layers in the backend region in a periphery region of the semiconductor die (block 715). For example, one or more of the semiconductor processing tools 102-114 may be used to form one or more second metallization layers 212 in the backend region 220 in a periphery region 206 of the semiconductor die 200, as described herein. In some implementations, the periphery region 206 surrounds the active device region 204 in a top view of the semiconductor die 200.

As further shown in FIG. 7, process 700 may include forming a top dielectric layer above the backend region after forming the one or more first metallization layers and the one or more second metallization layers (block 720). For example, one or more of the semiconductor processing tools 102-114 may be used to form a top dielectric layer 228 above the backend region 220 after forming the one or more first metallization layers 226 and the one or more second metallization layers 212, as described herein.

As further shown in FIG. 7, process 700 may include forming a barrier layer on the top dielectric layer (block 725). For example, one or more of the semiconductor processing tools 102-114 may be used to form a barrier layer 234 on the top dielectric layer 228, as described herein.

As further shown in FIG. 7, process 700 may include forming a metal layer on the barrier layer (block 730). For example, one or more of the semiconductor processing tools 102-114 may be used to form a metal layer 402 on the barrier layer 234, as described herein.

As further shown in FIG. 7, process 700 may include forming a capping layer on the metal layer (block 735). For example, one or more of the semiconductor processing tools 102-114 may be used to form a capping layer 404 on the metal layer 402, as described herein.

As further shown in FIG. 7, process 700 may include performing a first etch operation to etch the capping layer and the metal layer to form a test pad on the top dielectric layer in the periphery region (block 740). For example, one or more of the semiconductor processing tools 102-114 may be used to perform a first etch operation to etch the capping layer 404 and the metal layer 402 to form a test pad 408 on the top dielectric layer 228 in the periphery region 206, as described herein.

As further shown in FIG. 7, process 700 may include forming, after the first etch operation, sidewall spacers on sidewalls of the test pad (block 745). For example, one or more of the semiconductor processing tools 102-114 may be used to form, after the first etch operation, sidewall spacers 412 on sidewalls of the test pad 408, as described herein.

As further shown in FIG. 7, process 700 may include performing, after forming the sidewall spacers, a second etch operation to etch the barrier layer such that the barrier layer remains only under the test pad (block 750). For example, one or more of the semiconductor processing tools 102-114 may be used to perform, after forming the sidewall spacers 412, a second etch operation to etch the barrier layer 234 such that the barrier layer 234 remains only under the test pad 408 and the sidewall spacers 412, as described herein.

Process 700 may include additional implementations, such as any single implementation or any combination of implementations described below and/or in connection with one or more other processes described elsewhere herein.

In a first implementation, the first etch operation includes a dry etch operation, and the second etch operation comprises a wet etch operation using a wet etchant.

In a second implementation, alone or in combination with the first implementation, an etch rate of the wet etchant for the barrier layer 234 is greater than an etch rate of the wet etchant for the sidewall spacers 412.

In a third implementation, alone or in combination with one or more of the first and second implementations, the barrier layer 234 includes tantalum nitride (TaN), and the sidewall spacers 412 include at least one of a silicon oxide (SiOₓ), a silicon oxynitride (SiON), a silicon nitride (SiₓN_{y}), or an aluminum oxide (AlₓO_{y}).

In a fourth implementation, alone or in combination with one or more of the first through third implementations, process 700 includes removing the test pad 408 after performing the second etch operation, and forming a redistribution pad 210 over the barrier layer 234 in place of the test pad 408, where a bottom surface of the redistribution pad 210 and a bottom surface of the barrier layer 234 are co-planar.

In a fifth implementation, alone or in combination with one or more of the first through fourth implementations, the test pad 408 includes aluminum copper (AlCu), and the redistribution pad 210 includes titanium (Ti).

Although FIG. 7 shows example blocks of process 700, in some implementations, process 700 includes additional blocks, fewer blocks, different blocks, or differently arranged blocks than those depicted in FIG. 7. Additionally, or alternatively, two or more of the blocks of process 700 may be performed in parallel.

In this way, a highly selective wet etch technique is used to etch a barrier layer under a metal layer from which the test pads of a semiconductor die are formed in a periphery region of the semiconductor die. The wet etch technique involves the use of a wet etchant that has a high etch rate for the barrier layer and a very low etch rate (effectively a zero etch rate, in some cases) for a top dielectric layer on which the barrier layer is formed. Sidewall spacers may be formed on the sidewalls of the test pads to protect the test pads from being etched by the wet etchant. The low etch rate of the top dielectric layer reduces and/or minimizes over etching into the top dielectric layer, which reduces and/or minimizes the step height between the top dielectric layer and the test pads. Thus, when the test pads are replaced with redistribution pads after testing of the semiconductor die, the difference in height between the redistribution pads in the periphery region and redistribution pads in an active device region of the semiconductor die is reduced and/or minimized. This enables a pick and place tool to utilize more of the surface area of the redistribution pads of the semiconductor die to securely pick up and move the semiconductor die. This increases the productivity of the pick and place tool (the pick and place tool can spend less time attempting to securely pick up and move the semiconductor die, thereby processing a greater quantity of semiconductor dies) and/or reduces the likelihood of damage to the semiconductor die, among other examples.

As described in greater detail above, some implementations described herein provide a method. The method includes forming one or more semiconductor devices in an active device region of a semiconductor die. The method includes forming one or more first metallization layers in a backend region above the one or more semiconductor devices. The method includes forming one or more second metallization layers in the backend region in a periphery region of the semiconductor die, where the periphery region surrounds the active device region in a top view of the semiconductor die. The method includes forming a top dielectric layer above the backend region after forming the one or more first metallization layers and the one or more second metallization layers. The method includes forming a barrier layer on the top dielectric layer. The method includes forming a metal layer on the barrier layer. The method includes forming a capping layer on the metal layer. The method includes performing a first etch operation to etch the capping layer and the metal layer to form a test pad on the top dielectric layer in the periphery region. The method includes performing, after the first etch operation, a second etch operation to etch the barrier layer such that the barrier layer remains only under the test pad.

As described in greater detail above, some implementations described herein provide a method. The method includes forming one or more semiconductor devices in an active device region of a semiconductor die. The method includes forming one or more first metallization layers in a backend region above the one or more semiconductor devices. The method includes forming one or more second metallization layers in the backend region in a periphery region of the semiconductor die, where the periphery region surrounds the active device region in a top view of the semiconductor die. The method includes forming a top dielectric layer above the backend region after forming the one or more first metallization layers and the one or more second metallization layers. The method includes forming a barrier layer on the top dielectric layer. The method includes forming a metal layer on the barrier layer. The method includes forming a capping layer on the metal layer. The method includes performing a first etch operation to etch the capping layer and the metal layer to form a test pad on the top dielectric layer in the periphery region. The method includes forming, after the first etch operation, sidewall spacers on sidewalls of the test pad. The method includes performing, after forming the sidewall spacers, a second etch operation to etch the barrier layer such that the barrier layer remains only under the test pad and the sidewall spacers.

As described in greater detail above, some implementations described herein provide a semiconductor die. The semiconductor die includes an active device region that includes one or more semiconductor devices, a backend region above the one or more semiconductor devices, a top dielectric layer above the backend region, and a first redistribution pad above the top dielectric layer. The semiconductor die includes a periphery region, surrounding the active device region in a top view of the semiconductor die, that includes one or more metallization layers, the top dielectric layer above the one or more metallization layers, and a second redistribution pad, above the top dielectric layer, that includes a lower portion on the top dielectric layer and a raised portion above the lower portion, where a first portion of a top surface of the top dielectric layer under the lower portion and a second portion of the top surface of the top dielectric layer under the raised portion are in a same plane.

As used herein, “satisfying a threshold” may, depending on the context, refer to a value being greater than the threshold, greater than or equal to the threshold, less than the threshold, less than or equal to the threshold, equal to the threshold, not equal to the threshold, or the like.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming one or more semiconductor devices in an active device region of a semiconductor die;
forming one or more first metallization layers in a backend region above the one or more semiconductor devices;
forming one or more second metallization layers in the backend region in a periphery region of the semiconductor die,
wherein the periphery region surrounds the active device region in a top view of the semiconductor die;
forming a top dielectric layer above the backend region after forming the one or more first metallization layers and the one or more second metallization layers;
forming a barrier layer on the top dielectric layer;
forming a metal layer on the barrier layer;
forming a capping layer on the metal layer;
performing a first etch operation to etch the capping layer and the metal layer to form a test pad on the top dielectric layer in the periphery region; and
performing, after the first etch operation, a second etch operation to etch the barrier layer such that the barrier layer remains only under the test pad.

2. The method of claim 1, wherein the second etch operation comprises a wet etch operation using a wet etchant.

3. The method of claim 2, wherein the wet etchant comprises a combination of ammonium hydroxide (NH₄OH), hydrogen peroxide (H₂O₂), and water (H₂O).

4. The method of claim 3, wherein the hydrogen peroxide comprises a greater concentration by weight of the wet etchant than the ammonium hydroxide.

5. The method of claim 2, wherein the wet etchant comprises a combination of hydrochloric acid (HCl) and nitric acid (HNO₃).

6. The method of claim 5, wherein the hydrochloric acid comprises a greater concentration by weight of the wet etchant than the nitric acid.

7. The method of claim 2, wherein an etch rate of the wet etchant for the barrier layer is greater than an etch rate of the wet etchant for the top dielectric layer.

8. The method of claim 1, wherein the second etch operation stops on the top dielectric layer.

9. A method, comprising:
forming one or more semiconductor devices in an active device region of a semiconductor die;
forming one or more first metallization layers in a backend region above the one or more semiconductor devices;
forming one or more second metallization layers in the backend region in a periphery region of the semiconductor die,
wherein the periphery region surrounds the active device region in a top view of the semiconductor die;
forming a top dielectric layer above the backend region after forming the one or more first metallization layers and the one or more second metallization layers;
forming a barrier layer on the top dielectric layer;
forming a metal layer on the barrier layer;
forming a capping layer on the metal layer;
performing a first etch operation to etch the capping layer and the metal layer to form a test pad on the top dielectric layer in the periphery region;
forming, after the first etch operation, sidewall spacers on sidewalls of the test pad; and
performing, after forming the sidewall spacers, a second etch operation to etch the barrier layer such that the barrier layer remains only under the test pad and the sidewall spacers.

10. The method of claim 9, wherein the first etch operation comprises a dry etch operation; and
wherein the second etch operation comprises a wet etch operation using a wet etchant.

11. The method of claim 10, wherein an etch rate of the wet etchant for the barrier layer is greater than an etch rate of the wet etchant for the sidewall spacers.

12. The method of claim 9, wherein the barrier layer comprises at least one of:
tantalum (Ta),
tantalum nitride (TaN),
titanium (Ti), or
titanium nitride (TiN); and
wherein the sidewall spacers comprise at least one of:
a silicon oxide (SiOₓ),
a silicon oxynitride (SiON),
a silicon nitride (SiₓN_{y}), or
an aluminum oxide (AlₓO_{y}).

13. The method of claim 9, further comprising:
removing the test pad after performing the second etch operation; and
forming a redistribution pad over the barrier layer in place of the test pad,
wherein a bottom surface of the redistribution pad and a bottom surface of the barrier layer are co-planar.

14. The method of claim 13, wherein the test pad comprises aluminum copper (AlCu); and
wherein the redistribution pad comprises titanium (Ti).

15. A semiconductor die, comprising:
an active device region, comprising:
one or more semiconductor devices;
a backend region above the one or more semiconductor devices;
a top dielectric layer above the backend region; and
a first redistribution pad above the top dielectric layer; and
a periphery region, surrounding the active device region in a top view of the semiconductor die, comprising:
one or more metallization layers;
the top dielectric layer above the one or more metallization layers; and
a second redistribution pad, above the top dielectric layer, comprising:
a lower portion on the top dielectric layer; and
a raised portion above the lower portion,
wherein a first portion of a top surface of the top dielectric layer under the lower portion and a second portion of the top surface of the top dielectric layer under the raised portion are in a same plane.

16. The semiconductor die of claim 15, further comprising:
a barrier layer between the raised portion of the second redistribution pad and the top dielectric layer,
wherein the barrier layer is surrounded by the lower portion.

17. The semiconductor die of claim 16, wherein the barrier layer comprises recessed ends between the barrier layer and the lower portion of the second redistribution pad.

18. The semiconductor die of claim 16, wherein a bottom surface of the barrier layer and a bottom surface of the lower portion are in a same plane.

19. The semiconductor die of claim 15, wherein a thickness of the raised portion is included in a range of approximately 10 nanometers to approximately 80 nanometers.

20. The semiconductor die of claim 15, wherein a difference in height, between a top surface of the raised portion and a top surface of the first redistribution pad, is included in a range of approximately 10 nanometers to approximately 80 nanometers.
